(19) United States
(12) Patent Application Publication
(10) Pub. No.: US 2026/0310623 A1
(43) Pub. Date: Oct. 8, 2026

(54) POWER MANAGEMENT IN NETWORK DEVICES

(71) Applicant: Cisco Technology, Inc., San Jose, CA (US)

(72) Inventors: Alessandro Cevrero, Zurich (CH); Thomas Helmut Toifl, Gattikon (CH); Christian Ivo Menolfi, Langnau am Albis (CH); Ilter Ismailov Hyuseinov, Adliswil (CH)

(21) Appl. No.: 19/172,640

(22) Filed: Apr. 7, 2025

(51) Int. Cl. G06F 13/40; G06F 13/42; H03M 9/00

(52) U.S. Cl. CPC G06F 13/4072; G06F 13/4282; H03M 9/00

(57) ABSTRACT

Devices and methods for power management in network devices are described herein. In a transmitter network device, one or more processors, a memory, a common mode (CM) keeper circuit, and a Serializer/Deserializer (SerDes) circuit including a plurality of circuit elements, for example, a phase interpolator, a clock fan-up circuit, a Current Mode Logic (CML) driver circuit, a termination circuit, are provided. The memory includes a power management logic. The power management logic is configured to detect an absence of data for transmission and transition at least one of the plurality of circuit elements from a power-up state to a power-down state based on the detection of the absence of data for transmission. The CM keeper circuit is configured to maintain an output voltage of the SerDes circuit at a configured level upon the transition of the at least one of the plurality of circuit elements to the power-down state.

The present disclosure relates to wireless networking. More particularly, the present disclosure relates to power management in network devices.

### BACKGROUND

Network devices serve as the backbone of modern communication infrastructures. The network devices facilitate data exchange and enable connectivity across various networks, ranging from Local Area Networks (LANs) to Wide Area Networks (WANs). Managed via firmware or software interfaces, the network devices may contribute to building and maintaining robust and scalable network infrastructures. Examples of network devices may include routers, switches, access points, hubs, modems, or the like.

The network devices may include Serializer/Deserializer (SerDes) circuits to enable high-bandwidth data transmission. A SerDes circuit is an Integrated Circuit (IC) that converts data between serial and parallel formats. While SerDes circuits facilitate efficient communication, the SerDes circuits may also contribute to the overall power consumption in the network devices, particularly during periods of inactivity (for example, in the absence of data for transmission). Even when no data is being transmitted, SerDes circuits may remain operational to maintain link integrity and synchronization. The continuous operation of the SerDes circuits may lead to energy inefficiency, posing a challenge for power optimization in network devices.

### SUMMARY OF THE DISCLOSURE

Devices and methods for power management in network devices in accordance with embodiments of the disclosure are described herein. In many embodiments, a transmitter network device may include a Serializer/Deserializer (SerDes) circuit including a plurality of circuit elements, one or more processors, a memory communicatively coupled to the one or more processors, and a Common Mode (CM) keeper circuit. The memory may include a power management logic. The power management logic may be configured to detect an absence of data for transmission and transition at least one of the plurality of circuit elements from a power-up state to a power-down state based on the detection of the absence of data for transmission. The CM keeper circuit may be configured to maintain an output voltage of the SerDes circuit at a configured level upon the transition of the at least one of the plurality of circuit elements to the power-down state.

In a number of embodiments, the at least one of plurality of circuit elements may include two or more of the plurality of circuit elements, and the power management logic may be further configured to transition the two or more of the plurality of circuit elements from the power-up state to the power-down state in a staggered sequence based on the detection of the absence of data for transmission

In a variety of embodiments, the plurality of circuit elements comprises two or more of a phase interpolator, a clock fan-up circuit, a Current Mode Logic (CML) driver circuit, and a termination circuit.

In various embodiments, the plurality of circuit elements may further include the phase interpolator and one or more switches coupled to the phase interpolator, and the power management logic may further be configured to actuate the one or more switches to transition the phase interpolator from the power-up state to the power-down state.

In more embodiments, the plurality of circuit elements may further include the clock fan-up circuit and one or more switches coupled to the clock fan-up circuit, and the power management logic may further be configured to actuate the one or more switches to transition the clock fan-up circuit from the power-up state to the power-down state.

In additional embodiments, the plurality of circuit elements may further include the termination circuit and one or more switches coupled to the termination circuit, and the power management logic may further be configured to actuate the one or more switches to transition the termination circuit from the power-up state to the power-down state.

In further embodiments, the plurality of circuit elements may further include the CML driver circuit and a current source coupled to the CML driver circuit, and the power management logic may further be configured to deactivate the current source to transition the CML driver circuit from the power-up state to the power-down state.

In still more embodiments, the power management logic may further be configured to deactivate the current source after a configurable time period following a transition of the termination circuit from the power-up state to the power-down state.

In still further embodiments, the CML driver circuit may further include a pair of differential input terminals, and the power management logic may further be configured to control a gating of the pair of differential input terminals of the CML driver circuit, where the deactivation of the current source is based on the gating of the pair of differential input terminals.

In still additional embodiments, the transmitter network device may further include a switching element between the CM keeper circuit and one or more output terminals of the SerDes circuit, where the power management logic may further be configured to actuate the switching element to couple the CM keeper circuit to the one or more output terminals of the SerDes circuit based on the transition of the CML driver circuit to the power-down state, and where the maintaining of the output voltage of the SerDes circuit at the configured level may be based on the CM keeper circuit being coupled to the one or more output terminals.

In many more embodiments, the SerDes circuit may be configured to generate a power-down signal, and transmit the generated power-down signal to a receiver device indicating the power-down state of the at least one of the plurality of circuit elements.

In yet various embodiments, the SerDes circuit may be configured to transmit a reference clock signal to the receiver device upon the transition of the at least one of the plurality of circuit elements to the power-down state.

In yet more embodiments, the power management logic may further be configured to enable the CM keeper circuit based on the transition of the at least one of the plurality of circuit elements to the power-down state, and wherein the maintaining of the output voltage of the SerDes circuit at the configured level is based on the enabling of the CM keeper circuit.

In still yet more embodiments, the power management logic may further be configured to detect a presence of data for transmission, and transition the at least one of the plurality of circuit elements from the power-down state to the power-up state based on the detection of the presence of data for transmission.

In various embodiments, the power management logic may further be configured to disable the CM keeper circuit based on the transition of the at least one of the plurality of circuit elements from the power-down state to the power-up state.

In several embodiments, a receiver network device may include a SerDes circuit including a plurality of circuit elements, where the SerDes circuit may be configured to receive a power-down signal from a transmitter network device. The receiver network device may further include one or more processors and a memory communicatively coupled to the one or more processors. The memory may include a power management logic that may be configured to transition at least one of the plurality of circuit elements from a power-up state to a power-down state based on the reception of the power-down signal. The receiver network device may further include a CM keeper circuit coupled to the SerDes circuit. The CM keeper circuit may further be configured to maintain an output voltage of the SerDes circuit at a configured level upon the transition of the at least one of the plurality of circuit elements to the power-down state.

In a number of embodiments, the at least one of plurality of circuit elements may include two or more of the plurality of circuit elements, and the power management logic may further be configured to transition the two or more of the plurality of circuit elements from the power-up state to the power-down state in a staggered sequence based on the reception of the power-down signal.

In more embodiments, the power management logic may further be configured to receive a power-up signal from the transmitter network device, and transition the at least one of the plurality of circuit elements from the power-down state to the power-up state based on the reception of the power-up signal.

In furthermore embodiments, the power management logic may further be configured to receive a reference clock signal from the transmitter network device, and maintain a timing alignment with the transmitter network device during the power-down state based on the received reference clock signal.

In several more embodiments, a method in a transmitter network device may include detecting an absence of data for transmission, transitioning at least one of a plurality of circuit elements of a SerDes circuit in the transmitter network device from a power-up state to a power-down state based on the detection of the absence of data for transmission, and maintaining an output voltage of the SerDes circuit at a configured level using a CM keeper circuit of the transmitter network device upon the transition of the at least one of the plurality of circuit elements to the power-down state.

Other objects, advantages, novel features, and further scope of applicability of the present disclosure will be set forth in part in the detailed description to follow, and in part will become apparent to those skilled in the art upon examination of the following or may be learned by practice of the disclosure. Although the description above contains many specificities, these should not be construed as limiting the scope of the disclosure but as merely providing illustrations of some of the presently preferred embodiments of the disclosure. As such, various other embodiments are possible within its scope. Accordingly, the scope of the disclosure should be determined not by the embodiments illustrated, but by the appended claims and their equivalents.

### BRIEF DESCRIPTION OF DRAWINGS

The above, and other, aspects, features, and advantages of several embodiments of the present disclosure will be more apparent from the following description as presented in conjunction with the following several figures of the drawings.

FIG. 1 is a schematic block diagram of a networking environment in accordance with various embodiments of the disclosure;

FIG. 2 illustrates a communication layer architecture in accordance with various embodiments of the disclosure;

FIG. 3 is a communication environment including a transmitter network device and a receiver network device in accordance with various embodiments of the disclosure;

FIG. 4 illustrates a configuration of a transmitter network device when data is present for transmission in accordance with various embodiments of the disclosure;

FIG. 5 illustrates a configuration of a transmitter network device when data is absent for transmission in accordance with various embodiments of the disclosure;

FIG. 6 illustrates a circuit diagram of a Common Mode (CM) keeper circuit for Direct Current (DC) coupled Serializer/Deserializer (SerDes) circuit in accordance with various embodiments of the disclosure;

FIG. 7 illustrates a circuit diagram of a CM keeper circuit for Alternating Current (AC) coupled SerDes circuit in accordance with various embodiments of the disclosure;

FIG. 8 is a flowchart depicting a process for transitioning at least one of a plurality of circuit elements of a SerDes circuit in a transmitter network device from a power-up state to a power-down state in accordance with various embodiments of the disclosure;

FIG. 9 is a flowchart depicting a process for enabling a CM keeper circuit in a transmitter network device to maintain an output voltage of a SerDes circuit at a configured level in accordance with various embodiments of the disclosure;

FIG. 10 is a flowchart depicting a process for disabling a CM keeper circuit in a transmitter network device in accordance with various embodiments of the disclosure;

FIG. 11 is a flowchart depicting a process for transmitting a generated power-down signal to a receiver device indicating a power-down state of two or more of a plurality of circuit elements of a SerDes circuit in accordance with various embodiments of the disclosure;

FIG. 12 is a flowchart depicting a process for transmitting a reference clock signal to a receiver device in accordance with various embodiments of the disclosure;

FIG. 13 is a flowchart depicting a process for transitioning a phase interpolator of a SerDes circuit from a power-up state to a power-down state in accordance with various embodiments of the disclosure;

FIG. 14 is a flowchart depicting a process for transitioning a clock fan-up circuit of a SerDes circuit from a power-up state to a power-down state in accordance with various embodiments of the disclosure;

FIG. 15 is a flowchart depicting a process for transitioning a termination circuit of a SerDes circuit from a power-up state to a power-down state in accordance with various embodiments of the disclosure;

FIG. 16 is a flowchart depicting a process for transitioning a Current Mode Logic (CML) driver circuit of a SerDes circuit from a power-up state to a power-down state in accordance with various embodiments of the disclosure;

FIG. 17 is a flowchart depicting a process for controlling a gating of a pair of differential input terminals of a CML driver circuit of SerDes circuit to deactivate a current source coupled to the CML driver circuit in accordance with various embodiments of the disclosure;

FIG. 18 is a flowchart depicting a process for maintaining a timing alignment between a receiver network device and a transmitter network device during a power-down state in accordance with various embodiments of the disclosure;

FIG. 19 is a flowchart depicting a process for transitioning two or more of a plurality of circuit elements of a SerDes circuit in a receiver network device from a power-up state to a power-down state in a staggered sequence in accordance with various embodiments of the disclosure;

FIG. 20 is a flowchart depicting a process for disabling a CM keeper circuit of a receiver network device upon transition of at least one of a plurality of circuit elements of a SerDes circuit to a power-up state in accordance with various embodiments of the disclosure; and

FIG. 21 is a conceptual block diagram for one or more devices capable of executing components and logic for implementing the functionality and embodiments described above.

Corresponding reference characters indicate corresponding components throughout the several figures of the drawings. Elements in the several figures are illustrated for simplicity and clarity and have not necessarily been drawn to scale. For example, the dimensions of some of the elements in the figures might be emphasized relative to other elements for facilitating understanding of the various presently disclosed embodiments. In addition, common, but well-understood, elements that are useful or necessary in a commercially feasible embodiment are often not depicted in order to facilitate a less obstructed view of these various embodiments of the present disclosure.

### DETAILED DESCRIPTION

In response to the issues described above, devices and methods are discussed herein that can facilitate power management in network devices. A network device may include hardware and/or software components that facilitate communication and transmission of data between computers or other network-enabled devices. Examples of the network device may include a router, a switch, a hub, a modem, an access point, a server, a computing node, or the like.

The network device may include a Serializer/Deserializer (SerDes) circuit to enable high-bandwidth data transmission. Networks are typically designed to handle peak throughput demands, so during periods of low traffic, not all network links have to remain active. For example, during off-peak hours, when data transmission is minimal, certain links may be powered down or placed in an idle state. While the SerDes circuit facilitates efficient communication, the SerDes circuit may also contribute to the overall power consumption of the network device, particularly during periods of inactivity (for example, in the absence of data for transmission). Typically, the SerDes circuit operates continuously, even when no data transmission occurs, to maintain link integrity and synchronization. When the SerDes circuit is powered down and restarted, Phase-Locked Loop (PLL) acquisition time associated with the SerDes circuit may be significantly delayed. To ensure the PLL is quickly ready when data transmission resumes, the SerDes circuit remains operational. However, this continuous operation of the SerDes circuits can lead to energy inefficiency, presenting a significant challenge for power optimization in the network device.

To optimize power consumption in network devices equipped with SerDes circuits, the present disclosure introduces a dynamic power management solution. Present disclosure enables network devices to dynamically power down and power up the SerDes circuit, thereby reducing power consumption during periods of inactivity in data transmission. In many embodiments, a network device including a SerDes circuit may execute a power-down process when no data is received for transmission. During the power-down process, the network device may transition one or more circuit elements of the SerDes circuit from a power-up state to a power-down state while maintaining enough functionality for quick wake-up. The network device may include a Common Mode (CM) keeper circuit. Upon transitioning of the one or more circuit elements to the power-down state, the network device may enable the CM keeper circuit to couple the CM keeper circuit to the SerDes circuit based on the transition of the one or more circuit elements to the power-down state. The CM keeper circuit may be configured to maintain an output voltage of the SerDes circuit at a configured level upon the transition of the one or more circuit elements to the power-down state.

In a variety of embodiments, the network device may execute a power-up process when data is received for transmission. During the power-up process, the network device may transition the one or more circuit elements of the SerDes circuit from the power-down state to the power-up state, thereby restoring full functionality of the one or more circuit elements. Upon transitioning one or more circuit elements to the power-up state, the network device may disable the CM keeper circuit to decouple the CM keeper circuit to the SerDes circuit.

The dynamic power management approach allows for the selective powering down of one or more circuit elements of the SerDes circuit during periods of inactivity, such as when there is no data to be transmitted, thereby reclaiming power that would otherwise be consumed to keep the link active when no data is being transmitted. When data becomes available for transmission, the circuit elements can be quickly powered up, restoring full operational capacity without delay. This capability reduces unnecessary power consumption during periods of inactivity and optimizes the overall energy efficiency of the network, ensuring that power is utilized only when data transmission is required. This dynamic power management approach enables more efficient use of network resources, contributing to lower operational costs and enhanced sustainability.

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like), or an embodiment combining software and hardware aspects that may all generally be referred to herein as a “function,” “module,” “apparatus,” or “system.” Furthermore, aspects of the present disclosure may take the form of a computer program product embodied in one or more non-transitory computer-readable storage media storing computer-readable and/or executable program code. Many of the functional units described in this specification have been labeled as functions, in order to emphasize their implementation independence more particularly. For example, a function may be implemented as a hardware circuit comprising custom VLSI circuits or gate arrays, off-the-shelf semiconductors such as logic chips, transistors, or other discrete components. A function may also be implemented in programmable hardware devices such as via field programmable gate arrays, programmable array logic, programmable logic devices, or the like.

Functions may also be implemented at least partially in software for execution by various types of processors. An identified function of executable code may, for instance, comprise one or more physical or logical blocks of computer instructions that may, for instance, be organized as an object, procedure, or function. Nevertheless, the executables of an identified function need not be physically located together but may comprise disparate instructions stored in different locations which, when joined logically together, comprise the function and achieve the stated purpose for the function.

Indeed, a function of executable code may include a single instruction, or many instructions, and may even be distributed over several different code segments, among different programs, across several storage devices, or the like. Where a function or portions of a function are implemented in software, the software portions may be stored on one or more computer-readable and/or executable storage media. Any combination of one or more computer-readable storage media may be utilized. A computer-readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer-readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object-oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (“PCB”) or the like. Each of the functions and/or modules described herein, in certain embodiments, may alternatively be embodied by or implemented as a component.

A circuit, as used herein, comprises a set of one or more electrical and/or electronic components providing one or more pathways for electrical current. In various embodiments, a circuit may include a return pathway for electrical current, so that the circuit is a closed loop. In another embodiment, however, a set of components that does not include a return pathway for electrical current may be referred to as a circuit (e.g., an open loop). For example, an integrated circuit may be referred to as a circuit regardless of whether the integrated circuit is coupled to the ground (as a return pathway for electrical current) or not. In various embodiments, a circuit may include a portion of an integrated circuit, an integrated circuit, a set of integrated circuits, a set of non-integrated electrical and/or electrical components with or without integrated circuit devices, or the like. In one embodiment, a circuit may include custom VLSI circuits, gate arrays, logic circuits, or other integrated circuits; off-the-shelf semiconductors such as logic chips, transistors, or other discrete devices; and/or other mechanical or electrical devices. A circuit may also be implemented as a synthesized circuit in a programmable hardware device such as a field programmable gate array, programmable array logic, programmable logic device, or the like (e.g., as firmware, a netlist, or the like). A circuit may comprise one or more silicon integrated circuit devices (e.g., chips, die, die planes, packages) or other discrete electrical devices, in electrical communication with one or more other components through electrical lines of a printed circuit board, or the like. Each of the functions and/or modules described herein, in certain embodiments, may be embodied by or implemented as a circuit.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Further, as used herein, reference to reading, writing, storing, buffering, and/or transferring data can include the entirety of the data, a portion of the data, a set of the data, and/or a subset of the data. Likewise, reference to reading, writing, storing, buffering, and/or transferring non-host data can include the entirety of the non-host data, a portion of the non-host data, a set of the non-host data, and/or a subset of the non-host data.

Lastly, the terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps, or acts are in some way inherently mutually exclusive.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

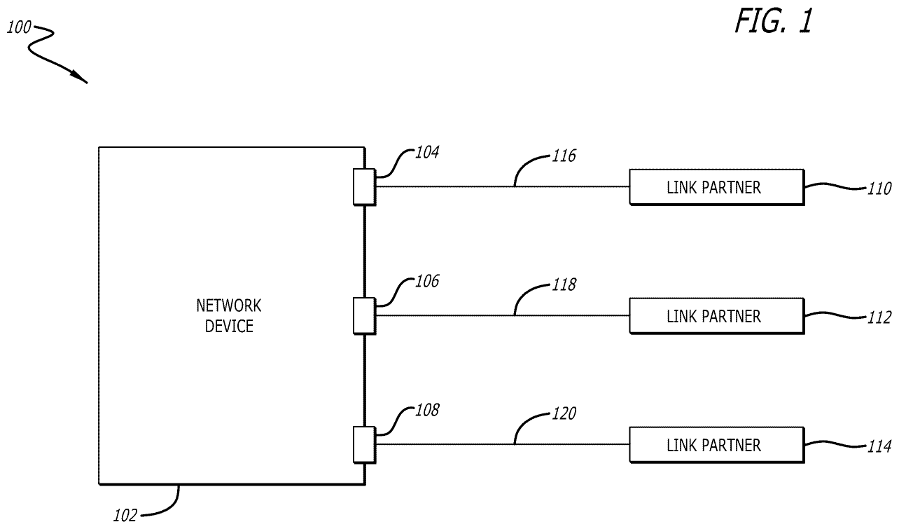

Referring to FIG. 1, a schematic block diagram of a networking environment 100 in accordance with various embodiments of the disclosure is shown. The embodiments depicted in FIG. 1 may show the networking environment 100 which can correspond to a network or a portion of the network. In many embodiments, the networking environment 100 may include a network device 102.

The network device 102 may include hardware and/or software components that facilitate communication and transmission of data between computers or other network-enabled devices. In a network, the network device 102 may contribute to establishing and maintaining connections. Examples of the network device 102 may include a router, a switch, a hub, a modem, an access point, a server, a computing node, or the like. The network device 102 may include various ports that facilitate network connectivity. In a number of embodiments, the network device 102 may include a plurality of ports, of which ports 104-108 are shown. In a variety of embodiments, the ports 104-108 may correspond to Ethernet ports.

In more embodiments, the networking environment 100 may include a plurality of link partners associated with the network device 102 (e.g., the plurality of ports). A link partner can correspond to a network device that couples to another network device via a network link. A network link may be a communication pathway that can couple two or more network devices, enabling data transmission between them. In additional embodiments, the plurality of link partners may include link partners 110-114 associated with the ports 104-108, respectively. Examples of the link partners 110-114 may include Wireless LAN Controllers (WLCs), switches, access points, servers, modems, routers, Voice over Internet Protocol (VoIP) devices, or the like.

As illustrated in FIG. 1, the link partner 110 may be coupled to the port 104 of the network device 102 by way of a link 116. Similarly, the link partner 112 may be coupled to the port 106 of the network device 102 by way of a link 118. Further, the link partner 114 may be coupled to the port 108 of the network device 102 by way of a link 120. In further embodiments, each link partner may include a port to facilitate coupling to a port of the network device. The network device 102 may thus communicate with the link partners 110-114 by way of the links 116-120, respectively.

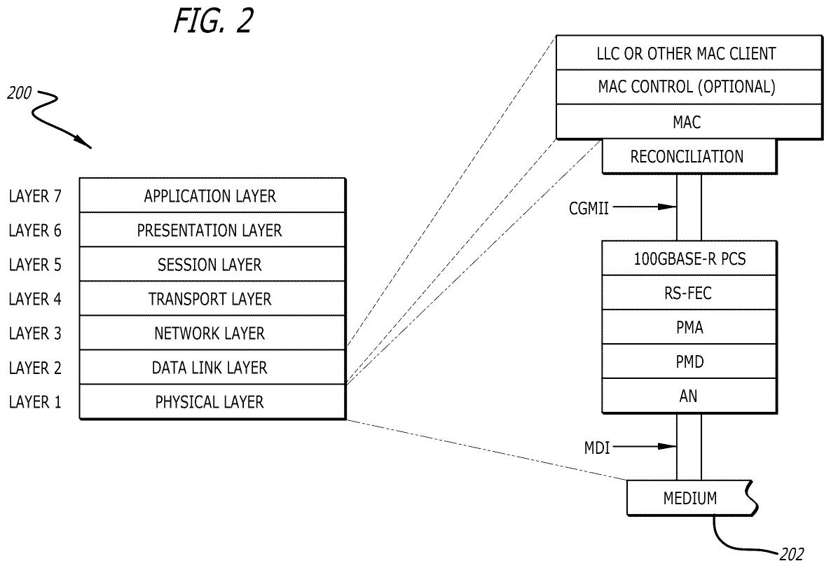

Although a specific embodiment for the networking environment 100 is described above with respect to FIG. 1, any of a variety of systems and/or processes may be utilized in accordance with embodiments of the disclosure. For example, the networking environment 100 may include a different number of link partners coupled to an equivalent number of ports of the network device 102 by way of an equivalent number of links. The elements depicted in FIG. 1 may also be interchangeable with other elements of FIGS. 2-21 as required to realize a particularly desired embodiment.

Referring to FIG. 2, a communication layer architecture 200 in accordance with various embodiments of the disclosure is shown. In a number of embodiments, the communication layer architecture 200 may be utilized to enable various communication mechanisms described herein. In many embodiments, the communication layer architecture 200 may be structured based on an Open Systems Interconnection (OSI) model. The communication layer architecture 200 may include seven layers. The seven layers may include, for example: a physical layer (Layer 1), a data link layer (Layer 2), a network layer (Layer 3), a transport layer (Layer 4), a session layer (Layer 5), a presentation layer (Layer 6), and an application layer (Layer 7). The physical layer is the lowest layer in the communication layer architecture 200, and the application layer is the highest layer in the communication layer architecture 200.

In several embodiments, the physical layer may transmit and receive unstructured raw data between a device, such as a Network Interface Controller (NIC), Ethernet hub, or network switch, and a physical transmission medium. The physical layer may facilitate conversion of digital bits into electrical, radio, or optical signals. The physical layer specifications outline aspects such as voltage levels, timing of voltage shifts, data rates, maximum transmission distances, modulation techniques, methods of channel access, and types of physical connectors. In more embodiments, bit rate control may be performed at the physical layer and may define transmission mode as simplex, half duplex, or full duplex.

In still more embodiments, the data link layer may be a protocol layer that transfers data between nodes on a network segment across the physical layer. The data link layer may provide functional and procedural means to transfer data between network entities and may also provide the means to detect and possibly correct errors that can occur in the physical layer. The data link layer provides for transfer of data frames between hosts connected to a physical link. The protocols of the data link layer may respond to service requests from the network layer, and perform their function by issuing service requests to the physical layer. In numerous embodiments, the data link layer may include one or more sublayers such as a Logical Link Control (LLC) sublayer (or Media Access Control (MAC) client), MAC control sublayer (optional), and MAC sublayer. The LLC sublayer may multiplex protocols running at the top of the data link layer, and may optionally provide flow control, acknowledgment, and error notification. The LLC sublayer may provide addressing and control of the data link. The LLC sublayer may specify which mechanisms are to be used for addressing stations over the transmission medium and for controlling the data exchanged between the originator and recipient machines. The MAC sublayer may determine who is allowed to access the media at any one time. Other times the MAC sublayer may refer to a frame structure delivered based on MAC addresses inside. The MAC sublayer may also perform frame synchronization, which determines the start and end of each frame of data in the transmission bitstream.

In some more embodiments, the network layer may provide the means of transferring variable-length network packets from a source to a destination host via one or more networks. The network layer may respond to service requests from the transport layer and issues service requests to the data link layer. Functions of the network layer include, but are not limited to, connectionless communication, host addressing, and message forwarding.

In further embodiments, the transport layer may provide functional and procedural means of transferring variable-length data sequences from a source host to a destination host from one application to another across a network while maintaining the quality-of-service functions. The transport layer may also control the reliability of a given link between a source and destination host through flow control, error control, and acknowledgments of sequence and existence.

In many further embodiments, the session layer may manage and control the dialogue between two devices in a communication session. The session layer may establish, maintain, and terminate the session, ensuring that data exchange occurs in a synchronized and organized manner. The session layer may handle full-duplex or half-duplex communication, ensuring proper synchronization with mechanisms such as checkpoints and providing recovery in case of disruptions. The session layer may also facilitate tasks such as authentication and session restoration.

In yet many embodiments, the presentation layer may translate, format, and encrypt data between the application layer and the transport layer. The presentation layer may ensure that the data sent from the application layer is in a readable format for the receiving application, managing tasks such as data compression, encryption, and conversion between different data formats (e.g., from American Standard Code for Information Interchange (ASCII) to Extended binary coded decimal interchange code (EBCDIC)). The presentation layer may play a key role in data syntax and semantics, ensuring that different systems, which may use varying data representations, can still communicate effectively.

In yet more embodiments, the application layer may be the topmost layer of the communication layer architecture 200 and may directly interact with end-user applications. The application layer may be responsible for providing network services and interfaces that allow software applications to communicate over a network. The application layer may enable a wide range of services, including file transfers, email, web browsing, and network management. The application layer may ensure that data is formatted and transmitted by the applications on both ends of the communication.

As shown in the example embodiment of FIG. 2, a 100 Gigabits per second (Gbps) Ethernet physical layer may include a 100GBASE-R PCS physical coding sublayer. Ethernet at 100 Gbps speeds (100GBASE-R) may follow a layered structure within the physical layer to ensure reliable data transmission over different media types. The Physical Coding Scheme (PCS) may be responsible for encoding and decoding data before transmission. The PCS may convert MAC-layer frames into a format suitable for transmission over the physical medium. The 100GBASE-R PCS may split the data into multiple lanes (for example, 4×25G or 10×10G lanes) for transmission over fiber or copper. Reed-Solomon Forward Error Correction (RS-FEC) in 100GBASE-R PHY may ensure reliable data transmission, especially over long distances. A Physical Medium Dependent (PMD) sublayer may deal with actual transmission of signals over the physical medium. The PMD may be responsible for transmitter and receiver operations, ensuring signal integrity. A Physical Medium Attachment (PMA) sublayer may act as an interface between the PCS and PMD. Auto-Negotiation (AN) is a mechanism used in Ethernet to enable two connected devices to automatically select common transmission parameters, such as speed and duplex mode. Auto-Negotiation may ensure compatibility and optimal performance when different Ethernet devices connect. A Medium Dependent Interface (MDI) may be a physical connection interface that may link a networking device (such as a switch, router, or NIC) to a transmission medium (such as copper cables or fiber optics). For example, the MDI may refer to the physical layer's pins and connectors, which transmit and receive data. Medium 202 may refer to a physical transmission channel used for data communication. Examples of the medium 202 may include, but are not limited to copper wires, fiber optics, and wireless signals.

In additional embodiments, the reconciliation sublayer may serve as an interface between the MAC sublayer and the PCS sublayer. The reconciliation sublayer may perform various functions such as signal mapping, encoding and decoding, clock synchronization, control signal handling, and data rate adaptation. Further, Common Gigabit Media Independent Interface (CGMII) may be an interface between the data link layer and the physical layer. The CGMII may be responsible for data transmission between the data link layer and the physical layer, and synchronization of data streams.

Although a specific embodiment for a communication layer architecture 200 is described above with respect to FIG. 2, any of a variety of systems and/or processes may be utilized in accordance with embodiments of the disclosure. For example, various aspects described herein may reside or be carried out on one layer, or a plurality of layers. The elements depicted in FIG. 2 may also be interchangeable with other elements of FIG. 1 and FIGS. 3-21 as required to realize a particularly desired embodiment.

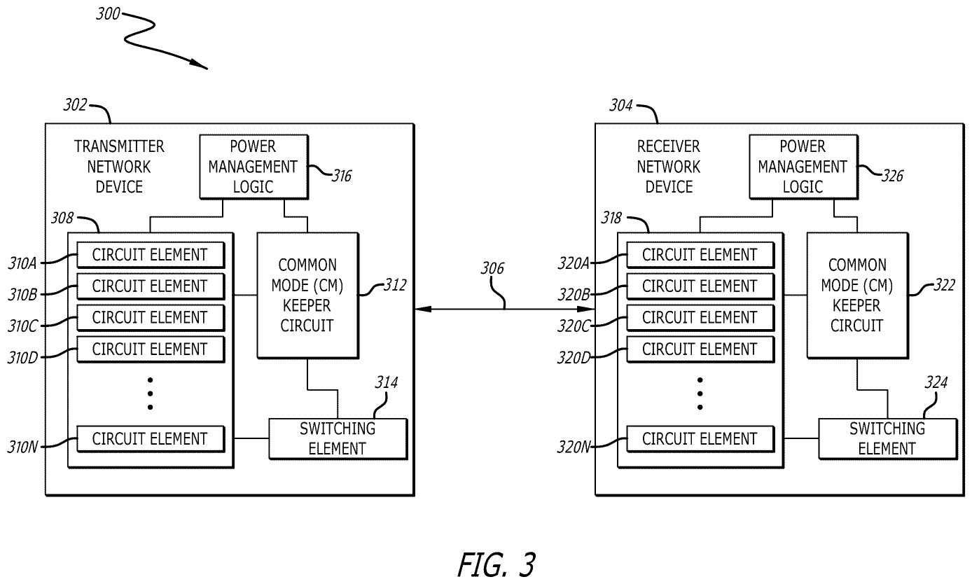

Referring to FIG. 3, a communication environment 300, including a transmitter network device 302 and a receiver network device 304 in accordance with various embodiments of the disclosure is shown. The transmitter network device 302 may be configured to receive data from a communication link, such as an Ethernet link, a fiber-optic link, a wireless link, or any other type of communication medium. Upon receiving the data, the transmitter network device 302 may be configured to process and/or transmit the data to the receiver network device 304 for further processing. For example, the transmitter network device 302 may be a router, and the receiver network device 304 may be a server. The transmitter network device 302 and the receiver network device 304 may be configured to communicate with each other via a communication interface 306. The communication interface 306 may facilitate data exchange between the transmitter network device 302 and the receiver network device 304. The communication interface 306 may be one of a physical interface or a logical interface through which data is transmitted between the transmitter network device 302 and the receiver network device 304.

In a number of embodiments, the transmitter network device 302 may include a Serializer/Deserializer (SerDes) circuit 308. The SerDes circuit 308 may be configured to serializing data for transmission over high-speed links. In an example, the SerDes circuit 308 may be configured to serialize the data from a parallel format (where multiple bits are transmitted simultaneously) into a serial format (where bits are sent one at a time) for transmission to the receiver network device 304. The SerDes circuit 308 may include a plurality of circuit elements 310A, 310B, 310C, 310D, . . . , 310N (hereinafter collectively referred to as the “plurality of circuit elements 310A-N”). The plurality of circuit elements 310A-N may include one or more analog circuit elements and/or one or more digital circuit elements. In a non-limiting example, the plurality of circuit elements 310A-N may include a phase interpolator, a clock fan-up circuit, a Current Mode Logic (CML) driver circuit, a termination circuit, a serializer, multiplexers (MUX), switches, input terminals, and/or output terminals. The phase interpolator may be configured to adjust a clock signal phase to synchronize data transmission. The clock fan-up circuit may be configured to distribute a single reference clock signal to various circuit elements of the SerDes circuit 308, ensuring synchronized operation of all circuit elements. The CML driver circuit may be configured to convert serialized data into high-speed differential transmission signals. The termination circuit may include a pair of resistors placed parallel to each other and between a pair of output terminals (interchangeably referred to as differential output terminals) of the SerDes circuit 308. In an example, the differential transmission signals may flow through the differential output terminals of the SerDes circuit 308. The termination circuit may be positioned at the end of the differential output terminals to match characteristic impedance of the differential transmission signals.

In many embodiments, the transmitter network device 302 may further include a Common Mode (CM) keeper circuit 312. The CM keeper circuit 312 may include one or more components, such as a source follower and an Operational Amplifier (OPAMP). The transmitter network device 302 may also include a switching element 314 between the SerDes circuit 308 and the CM keeper circuit 312. The switching element 314 may be actuated to selectively couple the CM keeper circuit 312 to the SerDes circuit 308 or decouple the CM keeper circuit 312 from the SerDes circuit 308, depending on operational conditions.

In various embodiments, the transmitter network device 302 may include a power management logic 316, which may be utilized to perform dynamic power management within the transmitter network device 302. The power management logic 316 may include various hardware and/or software components and be implemented in different configurations. For example, the power management logic 316 may include a set of instructions stored in memory, which carry out dynamic power management operations when executed by one or more processors.

In yet various embodiments, the receiver network device 304 may include a SerDes circuit 318. For instance, the SerDes circuit 318 may be configured to deserialize data upon reception. In an example, the receiver network device 304 may receive the data for deserializing from the SerDes circuit 308. The SerDes circuit 318 may include a plurality of circuit elements 320A, 320B, 320C, 320D, . . . , 320N (hereinafter collectively referred to as the “plurality of circuit elements 320A-N”). The plurality of circuit elements 320A-N may include one or more analog circuit elements and/or one or more digital circuit elements. In a non-limiting example, the plurality of circuit elements 320A-N may include a phase interpolator, a clock fan-up circuit, a CML driver circuit, a termination circuit, a deserializer, MUX, switches, input terminals, and/or output terminals. The functionality of the plurality of circuit elements 320A-N in the SerDes circuit 318 may substantially be the same as that of the plurality of circuit elements 310A-N in the SerDes circuit 308, as described herein. Any reference to specific elements or functionality in the SerDes circuit 308 may also apply to the SerDes circuit 318 unless explicitly stated otherwise.

In several embodiments, the receiver network device 304 may include a CM keeper circuit 322. The CM keeper circuit 322 may include one or more components, such as a source follower and an OPAMP. The receiver network device 304 may also include a switching element 324 between the SerDes circuit 318 and the CM keeper circuit 322. The switching element 324 may be actuated to selectively couple the CM keeper circuit 322 to the SerDes circuit 318 or decouple the CM keeper circuit 322 from the SerDes circuit 318, depending on the operational conditions.

In more embodiments, the receiver network device 304 may include a power management logic 326, which may be utilized to perform dynamic power management within the receiver network device 304. The power management logic 326 may include various hardware and/or software components and be implemented in different configurations. For example, the power management logic 326 may include a set of instructions stored in memory, which carry out dynamic power management operations when executed by one or more processors.

In numerous embodiments, as described above, the transmitter network device 302 may typically receive data through a communication link. The transmitter network device 302 may continuously or periodically monitor the communication link to detect incoming data intended for transmission. In many more embodiments, upon detecting data for transmission, the transmitter network device 302 may process and/or forward the data to other network devices, such as the receiver network device 304. However, during periods of low or no traffic, the transmitter network device 302 may identify that the communication link has become idle and is not actively transmitting data. In such scenarios, the transmitter network device 302 may detect an absence of data for transmission. When no data is being transmitted through the communication link, the transmitter network device 302 may initiate a power-down process through the power management logic 316 to conserve energy and minimize unnecessary power consumption. In still more embodiments, if no data is being transmitted, the SerDes circuit 308, which typically operates continuously, may be powered down or put into a low-power state.

In several more embodiments, during the power-down process, the power management logic 316 may be configured to transition at least one of the plurality of circuit elements 310A-N of the SerDes circuit 308 from a power-up state to a power-down state while maintaining functionality for prompt resumption of operation. The power-up state may represent an active, high-power mode, and the power-down state may represent a low-power mode, such as a sleep mode. A high-power mode may refer to a state where a circuit element is fully powered and active, utilizing power required to perform functions efficiently. A low-power mode may refer to a state where the power consumption of a circuit element is reduced by deactivating the circuit element. As a result, the circuit element may consume low power while maintaining the ability to resume full functionality when required promptly. In some more embodiments, the at least one of plurality of circuit elements 310A-N may include two or more of the plurality of circuit elements 310A-N. The power management logic 316 may further be configured to transition the two or more of the plurality of circuit elements 310A-N from the power-up state to the power-down state in a staggered sequence based on the detection of the absence of data for transmission. In an example, the power management logic 316 may not transition the two or more of the plurality of circuit elements 310A-N from the power-up state to the power-down state at the same time, but rather in a controlled order to optimize power conservation.

In additional embodiments, the power management logic 316 may be configured to enable the CM keeper circuit 312 based on the transition of the at least one of the plurality of circuit elements 310A-N to the power-down state. To enable the CM keeper circuit 312, the power management logic 316 may be configured to actuate the switching element 314 to couple the CM keeper circuit 312 to one or more output terminals of the SerDes circuit 308. In yet further embodiments, the CM keeper circuit 312 may be configured to maintain an output voltage of the communication interface 306 at a configured level upon the transition of the at least one of the plurality of circuit elements 310A-N to the power-down state. In an example, the configured level may be a predetermined voltage level that the CM keeper circuit 312 is designed to maintain for the communication interface 306 when the at least one of the plurality of circuit elements 310A-N are transitioned to the power-down state. This may ensure that the output voltage of the SerDes circuit 308 remains stable, even when the at least one of the plurality of circuit elements 310A-N is transitioned to the power-down state. By maintaining the output voltage of the SerDes circuit 308 at the configured level, the CM keeper circuit 312 ensures that the SerDes circuit 308 is ready to quickly and reliably recover when powered back on, minimizing any delay or issues during reactivation and ensuring smooth, continuous operation.

In yet several more embodiments, the SerDes circuit 308 may be configured to generate a power-down signal and transmit the generated power-down signal to a receiver device such as the receiver network device 304 via the communication interface 306 indicating the power-down state of the at least one of the plurality of circuit elements. In yet many additional embodiments, the SerDes circuit 308 may be configured to transmit a reference clock signal to the receiver device upon the transition of the at least one of the plurality of circuit elements 310A-N to the power-down state. The reference clock signal may ensure that the timing of the receiver network device 304 remains aligned with the transmitter network device 302, particularly with respect to a start time of the power-down process. This enables the receiver network device 304 to synchronize power management with the transmitter network device 302.

In further additional embodiments, the receiver network device 304 may receive the power-down signal from the transmitter network device 302 via the communication interface 306. In particular, the SerDes circuit 318 of the receiver network device 304 may receive the power-down signal from the transmitter network device 302. The power management logic 326 may be configured to initiate a power-down process to transition at least one of the plurality of circuit elements 320A-N from a power-up state to a power-down state based on the reception of the power-down signal.

In still various embodiments, the power management logic 326 may be configured to enable the CM keeper circuit 322 based on the transition of the at least one of the plurality of circuit elements 320A-N to the power-down state. To enable the CM keeper circuit 322, the power management logic 326 may be configured to actuate the switching element 324 to couple the CM keeper circuit 322 to one or more output terminals of the SerDes circuit 318. In still yet various more embodiments, the CM keeper circuit 322 may be configured to maintain an output voltage of the SerDes circuit 318 at a configured level upon the transition of the at least one of the plurality of circuit elements 320A-N to the power-down state. In yet additional embodiments, the at least one of plurality of circuit elements 320A-N may include two or more of the plurality of circuit elements. The power management logic 326 may be configured to transition the two or more of the plurality of circuit elements 320A-N from the power-up state to the power-down state in a staggered sequence based on the reception of the power-down signal.

In yet many embodiments, the receiver network device 304 may be configured to receive a reference clock signal from the transmitter network device 302. The power management logic 326 may be configured to maintain a timing alignment with the transmitter network device 302 during the power-down state based on the received reference clock signal. In yet more embodiments, the power management logic 326 may execute an occasional calibration to maintain the timing alignment between the transmitter network device 302 and the receiver network device 304.

In further embodiments, the power management logic 316 of the transmitter network device 302 may be further configured to detect a presence of data for transmission. The power management logic 316 may be configured to initiate a power-up process. During the power-up process, the power management logic 316 may be configured to transition the at least one of the plurality of circuit elements 310A-N from the power-down state to the power-up state based on the detection of the presence of data for transmission. In many further embodiments, the power management logic 316 may be configured to disable the CM keeper circuit 312 based on the transition of the at least one of the plurality of circuit elements 310A-N from the power-down state to the power-up state.

In several additional embodiments, the receiver network device 304 may be configured to receive the power-up signal from the transmitter network device 302. The power management logic 326 may be configured to initiate a power-up process. During the power-up process, the power management logic 326 may be configured to transition the at least one of the plurality of circuit elements 320A-N from the power-down state to the power-up state based on the reception of the power-up signal.

In numerous embodiments, dynamically powering down and powering up the SerDes circuits 308 and 318 allows for reclaiming the power that would otherwise be used to maintain an active communication link during periods of no data transmission. This approach ensures that the SerDes circuit 308 and the SerDes circuit 318 remain inactive when not in use, minimizing unnecessary power consumption, while still enabling prompt and efficient recovery when data transmission resumes, thereby optimizing overall power efficiency in both the transmitter network device 302 and the receiver network device 304.

Although a specific embodiment for the communication environment 300, including a transmitter network device 302 and a receiver network device 304 is described above with respect to FIG. 3, any of a variety of systems and/or processes may be utilized in accordance with embodiments of the disclosure. For example, the SerDes circuit 318 may generate a power-up signal and transmit the generated power-up signal to the receiver network device 304 indicating the power-up state of the at least one of the plurality of circuit elements 310A-N. The elements depicted in FIG. 3 may also be interchangeable with other elements of FIGS. 1, 2, and 4-21 as required to realize a particularly desired embodiment.

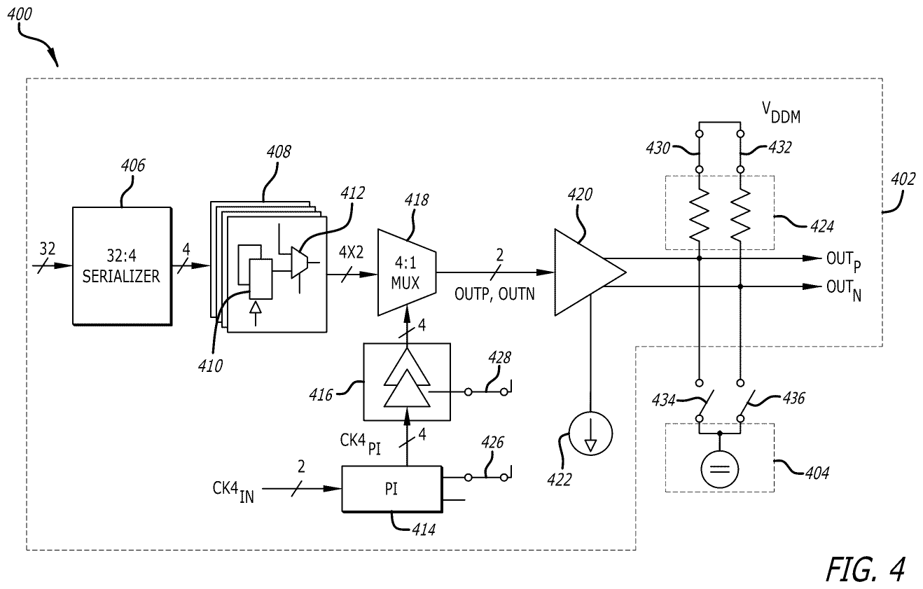

Referring to FIG. 4, a configuration of a transmitter network device 400 when data is present for transmission in accordance with various embodiments of the disclosure is shown. As shown in FIG. 4, the transmitter network device 400 may include a SerDes circuit 402 and a CM keeper circuit 404. In a number of embodiments, the SerDes circuit 402 may include a 32:4 serializer 406 (hereinafter referred to as the serializer 406). The serializer 406 may receive data in a parallel data format. For example, the serializer 406 may receive 32 bits of parallel data, and convert or serialize the 32 bits of parallel data into a 4-bit data stream.

In many embodiments, the SerDes circuit 402 may include a latching circuit 408. The latching circuit 408 may include a staggering latch 410 and a 2:1 Multiplexer (MUX) 412. The SerDes circuit 402 may further include a clock fan-up circuit 416, a phase interpolator 414 (also referred to as PI 414), and a 4:1 MUX 418. The clock fan-up circuit 416 may include one or more clock buffers. In various embodiments, the staggering latch 410 may be configured to align the timing of the 4-bit data stream. The 2:1 MUX 412 may be configured to control differential data provided to the 4:1 MUX 418 in an asynchronous manner. In numerous embodiments, during the normal state of the transmitter network device 400, for example, when the data is present or available for transmission, the 2:1 MUX 412 may be in an OFF state or may be deactivated.

In yet various embodiments, the 4:1 MUX 418 may output a differential signal pair, including a positive output signal (denoted as OUTP) and a negative output signal (denoted as OUTN). In some examples, the values of the positive output signal and the negative output signal may be complementary. For instance, if the positive output signal is high (logic 1), the negative output signal may be low (logic 0), and vice versa.

In several embodiments, the phase interpolator 414 may receive a 4-phase clock input signal, denoted as CK4_{IN}, which may be sourced from a Phase-Locked Loop (PLL) within the SerDes circuit 402 or an external clock source. The phase interpolator 414 may generate a clock output signal, denoted as CK4_{PI}, by adjusting the phase of the clock input signal to ensure proper timing alignment. As a result, the clock output signal may have adjusted phase. The clock fan-up circuit 416 may receive the clock output signal from the phase interpolator 414 and generate multiple phase-aligned clock output signals using the one or more clock buffers. Each phase-aligned clock output signal may be used by a circuit element of the SerDes circuit 402 to maintain timing accuracy and data integrity. For example, the clock fan-up circuit 416 may provide one of the multiple phase-aligned clock output signals to the 4:1 MUX 418.

In more embodiments, the SerDes circuit 402 may include a CML driver circuit 420 and a current source 422. The CML driver circuit 420 may include a pair of differential input terminals. The CML driver circuit 420 may receive the differential signal pair from the 4:1 MUX 418 through the pair of differential input terminals. In still more embodiments, the SerDes circuit 402 may include one or more output terminals. As shown in FIG. 4, the SerDes circuit 402 may include a pair of output terminals denoted as OUT_{P} and OUT_{N}, respectively. In some more embodiments, the current source 422 may provide constant current to the CML driver circuit 420. The CML driver circuit 420 may use the current to generate high-speed differential output signals for data transmission. In an example, the high-speed differential output signals may carry the serialized data. The CML driver circuit 420 may provide the differential output signals to a receiver device through the pair of output terminals.

In further embodiments, the SerDes circuit 402 may include a termination circuit 424. The termination circuit 424 may include a pair of resistors placed parallel to each other and between the pair of output terminals. The termination circuit 424 may ensure that the pair of output terminals are properly terminated, preventing reflections and ensuring signal integrity. The termination circuit 424 may match the impedance of the differential output signals and ensure that the differential output signals do not reflect back into the CML driver circuit 420. Without proper termination, reflections may occur, causing signal degradation and leading to data errors. The pair of resistors in the termination circuit 424 may help dissipate the energy from the differential output signals.

In many further embodiments, the SerDes circuit 402 may include a plurality of switches to manage power operations of the clock fan-up circuit 416, the phase interpolator 414, the CML driver circuit 420, and the termination circuit 424. As a non-limiting example, the plurality of switches may include a first switch 426 connected to the phase interpolator 414, a second switch 428 connected to the clock fan-up circuit 416, and a third switch 430 and a fourth switch 432 connected to the termination circuit 424. In yet many embodiments, the first switch 426, the second switch 428, the third switch 430, and the fourth switch 432 may be connected to a power source. In still various embodiments, the transmitter network device 400 may include a fifth switch 434 and a sixth switch 436 to selectively couple or decouple the CM keeper circuit 404 from the SerDes circuit 402.

In additional embodiments, when data is present for transmission, the first switch 426, the second switch 428, the third switch 430, and the fourth switch 432 may be in a closed state (as shown in FIG. 4), ensuring that the corresponding circuit elements are powered on and operational. The closed state of the first switch 426, the second switch 428, the third switch 430, and the fourth switch 432 may enable power delivery to these circuit elements, allowing the circuit elements to perform their functions effectively and maintain the integrity of the data transmission process. In numerous embodiments, during the presence of data for transmission, the fifth switch 434 and the sixth switch 436 may be in an open state, thereby decoupling the CM keeper circuit 404 from the SerDes circuit 402.

Although a specific embodiment for the configuration of the transmitter network device 400 when data is present for transmission is described above with respect to FIG. 4, any of a variety of systems and/or processes may be utilized in accordance with embodiments of the disclosure. For example, a receiver network device may function in a similar way as the transmitter network device 400 when data is present for transmission. The elements depicted in FIG. 4 may also be interchangeable with other elements of FIGS. 1-3 and 5-21 as required to realize a particularly desired embodiment.

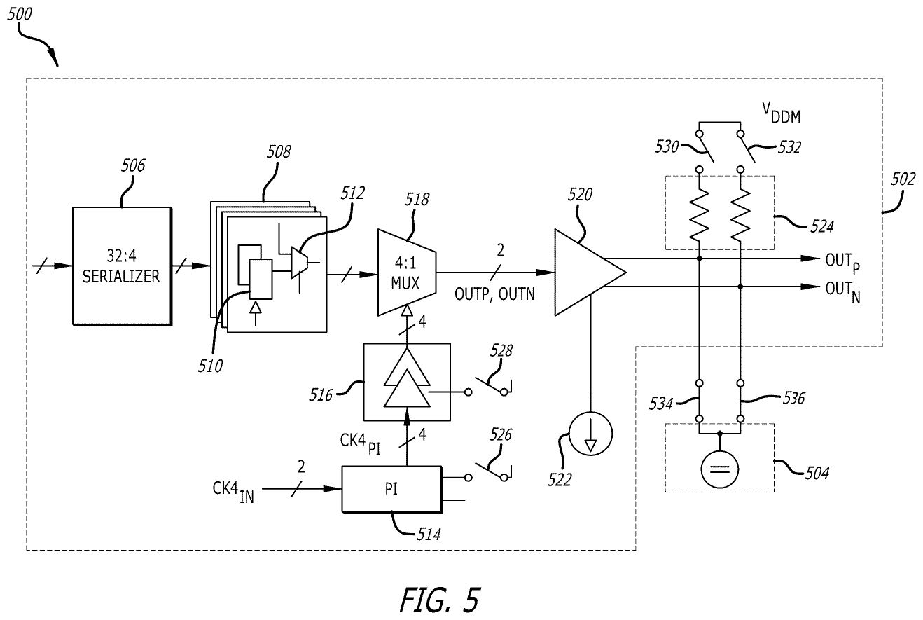

Referring to FIG. 5, a configuration of a transmitter network device 500 when data is absent for transmission in accordance with various embodiments of the disclosure is shown. As shown in FIG. 5, the transmitter network device 500 may include a SerDes circuit 502 and a CM keeper circuit 504. In a number of embodiments, the SerDes circuit 502 may include a plurality of circuit elements such as a 32:4 serializer 506, a latching circuit 508, a staggering latch 510, a 2:1 MUX 512, a clock fan-up circuit 516, a phase interpolator 514 (also referred to as PI 514), a 4:1 MUX 518, a CML driver circuit 520, a current source 522, a termination circuit 524. The CML driver circuit 520 may include a pair of differential input terminals.

In many embodiments, the SerDes circuit 502 may include a plurality of switches. The plurality of switches may include a first switch 526, a second switch 528, a third switch 530, and a fourth switch 532. In various embodiments, the first switch 526, the second switch 528, the third switch 530, and the fourth switch 532 may be connected to a power source. In yet various embodiments, the transmitter network device 400 may include a fifth switch 534 and a sixth switch 536 to selectively couple or decouple the CM keeper circuit 504 from the SerDes circuit 502. In an example, the fifth switch 534 and the sixth switch 536 may collectively be referred to as a switching element.

In several embodiments, the transmitter network device 500 may monitor data for transmission. In some examples, the transmitter network device 500 may actively monitor a communication link to detect the availability of data for transmission. In more embodiments, when a communication link is idle, meaning no data is actively being transmitted, the link may not engage in data transfer. During such idle periods, the transmitter network device 500 may detect an absence of data for transmission.

In still more embodiments, upon detecting the absence of data for transmission, the transmitter network device 500 may initiate a power-down process or sequence. During the power-down process, the transmitter network device 500 may be configured to transition one or more of the plurality of circuit elements from a power-up state to a power-down state. The power-up state may represent an active, high-power mode, while the power-down state may represent a low-power mode, such as a sleep mode. In the high-power mode, a circuit element is fully powered and operational, utilizing necessary power required to perform its function efficiently. In contrast, the low-power mode reduces by deactivating the circuit element.

In some more embodiments, to initiate the power-down process, the transmitter network device 500 may actuate the first switch 526 to transition the phase interpolator 514 from a power-up state to a power-down state. As shown in FIG. 5, the first switch 526 is actuated to an open state, causing the phase interpolator 514 to be deactivated, and thus preventing the phase interpolator 514 from consuming power.

In further embodiments, as a step of the power-down process, the transmitter network device 500 may actuate the second switch 528 to transition the clock fan-up circuit 516 from a power-up state to a power-down state. As shown in FIG. 5, the second switch 528 is actuated to an open state, causing the clock fan-up circuit 516 to be deactivated, thus preventing the clock fan-up circuit 516 from consuming power.

In many further embodiments, as an additional step of the power-down process, the transmitter network device 500 may actuate the third switch 530 and the fourth switch 532 to transition the termination circuit 524 from a power-up state to a power-down state. As shown in FIG. 5, the third switch 530 and the fourth switch 532 are actuated to an open state, causing the termination circuit 524 to be deactivated, thereby preventing the termination circuit 524 from consuming power. In yet many embodiments, when the termination circuit 524 is transitioned from the power-up state to the power-down state, current flowing to the CML driver circuit 520 may remain ON to prevent an output of the termination circuit 524 from reaching V_{DDM}, thus avoiding overvoltage condition or voltage spikes.

In yet more embodiments, as a further step of the power-down process, the transmitter network device 500 may deactivate a current source to transition the CML driver circuit 520 from a power-up state to a power-down state. In still various embodiments, the transmitter network device 500 may be configured to deactivate the current source after a configurable time period to turn OFF the current following a transition of the termination circuit 524 from the power-up state to the power-down state. In a non-limiting example, the configurable time period may be in a range of 70 picosecond to 100 picosecond. In several additional embodiments, the transmitter network device 500 may be configured to control a gating of the pair of differential input terminals of the CML driver circuit 520 to deactivate the current source. In still various embodiments, the CML driver circuit 520 is transitioned to the power-down state shortly after the termination circuit 524 is transitioned to the power-down state, to prevent the CML driver current from discharging common mode of the termination circuit 524 output.

In various embodiments, during the power-down process, the 2:1 MUX 512 is turned ON or may be activated. The 2:1 MUX 512 may set (or overwrite) the positive output signal OUTP and the negative output signal OUTN to logic low (logic 0). As a result, both the positive and negative output signals are set to zero (0). When both the positive and negative output signals are set to zero (0), no current flows to the output terminals OUT_{P} and OUT_{N} and the output is turned off. Further, no current is consumed by the CML driver circuit 520. Consequently, the CML driver circuit 520 is transitioned from the power-up state to the power-down state. After a certain period, the polarity of the positive and negative output signals OUTP and OUTN may be inverted, with the positive output signals OUTP being set to a constant logic 0 and the negative output signal OUTN also set to a constant logic 0. This adjustment may be performed to maintain DC balance.

In several additional embodiments, the transmitter network device 500 may be configured to enable the CM keeper circuit 504 based on the transition of the at least one of the plurality of circuit elements to the power-down state. When the CM keeper circuit 504 is enabled, the CM keeper circuit 504 may be configured to maintain an output voltage of the SerDes circuit 502 at the configured level. In numerous embodiments, to enable the CM keeper circuit 504, the transmitter network device 500 may actuate the fifth switch 534 and the sixth switch 536 to couple the CM keeper circuit 504 to one or more output terminals of the SerDes circuit 502.

Although, it has been described above that the phase interpolator 514, the clock fan-up circuit 516, the termination circuit 524, and the CML driver circuit 520 are transitioned from the power-up state to the power-down state in a specific sequence, in many more embodiments, the phase interpolator 514, the clock fan-up circuit 516, the termination circuit 524, and the CML driver circuit 520 may be transitioned from the power-up state to the power-down state in a staggered sequence. According to the staggered sequence, each circuit element may be powered down at different times, depending on operational requirements and current data transmission needs. As a result, overall power consumption of the transmitter network device 500 is reduced, thereby ensuring that only the necessary circuit elements remain active during idle periods. In further additional embodiments, instead of transitioning all the circuit elements to the power-down state, only one of the phase interpolator 514, the clock fan-up circuit 516, the termination circuit 524, and the CML driver circuit 520 may be transitioned from the power-up state to the power-down state at any given time. By selectively deactivating only the required circuit elements, power consumption in SerDes circuit 502 may be reduced, while still maintaining the necessary functionality for data transmission.

In several more embodiments, as described above, the transmitter network device 500 may actively monitor the communication link to detect the availability of data for transmission. When data is detected for transmission, the transmitter network device 500 may initiate a power-up process or sequence. During the power-up process, the transmitter network device 500 may be configured to transition the at least one of the plurality of circuit elements from the power-down state to the power-up state.

In several more embodiments, to initiate the power-up process, the transmitter network device 500 may actuate the first switch 526 to transition the phase interpolator 514 from the power-down state to the power-up state. The first switch 526 may be actuated to a closed state, causing the phase interpolator 514 to be activated.

In further embodiments, as a step of the power-up process, the transmitter network device 500 may turn ON the current flowing to the CML driver circuit 520 to transition the CML driver circuit 520 from the power-down state to the power-up state. The transmitter network device 500 may further set a Digital-to-Analog Converter (DAC) code for the CML driver circuit 520. In an example, the transmitter network device 500 may set +127 DAC code for the CML driver circuit 520 by using logic after staggering latches of the 4:1 MUX 518.

In numerous embodiments, as part of the power-up process, the 2:1 MUX 512 may set (or overwrite) the positive output signal OUTP to constant logic high (logic 1) and the negative output signal of OUTN to a constant logic low (logic 0), regardless of the data received from the 32:4 serializer 506 and independent of the presence of a clock at the 4:1 MUX 518. As may be understood, when the power-up process begins for the transmitter network device 500, no clock is available initially because the phase interpolator 514 and clock fan-up circuit 516 require additional time to transition from the power-down state to the power-up state. By setting the positive output signal OUTP to a constant 1 and the negative output signal OUTN to a constant 0, current flows to the output terminal OUT_{P}, thereby generating a signal even in the absence of a clock at the 4:1 MUX 518.

In an example scenario, in a normal state (e.g., when data transmission can occur), the positive output signal OUTP and the negative output signal OUTN carry data received from the 32:4 serializer 506. Specifically, the positive output signal OUTP may carry data “d” received from the 32:4 serializer 506, while the negative output signal OUTN may carry a logical complement of the data “d”, e.g., not(d). Further, in a power-down state, regardless of the data received from the 32:4 serializer 506, the positive output signal OUTP and the negative output signal OUTN may be set to logic low (logic 0) without requiring the clock at the 4:1 MUX 518. Additionally, in a power-up state (e.g., while waking up from the power-down state before the normal state is achieved), regardless of the data received from the 32:4 serializer 506, the positive output signal OUTP and the negative output signal OUTN may be set to logic high (logic 1) without requiring the clock at the 4:1 MUX 518. An example table describing the states of the input data from the 32:4 serializer 506, the positive output signal OUTP, and the negative output signal OUTN of the transmitter network device 500 for the normal, power-down, and power-up states is shown below:

| | Input Data | OUTP | OUTN |
|---|---|---|---|
| Normal state | d | d | not(d) |
| Power_down state | x | 0 | 0 |
| Power_up state | x | 1 | 1 |

In one or more embodiments, during the normal state of the transmitter network device 500, the transmitter network device 500 operates as expected, and the 32:4 serializer 506 transmits data. As shown in the table above, “d” represents the input data bit from the 32:4 serializer 506, OUTP=d indicates that the output corresponds to the serialized data value d, and OUTN=not(d) indicates that the output is the inverse of the input data d. During the power-down state of the transmitter network device 500, no clock is required for operation. Additionally, there is no input data from the 32:4 serializer 506. In this state, OUTP=0 and OUTN=0, indicating both the positive and negative output signals are set to zero (0), preventing any current from flowing to either output terminal OUT_{P} or OUT_{N}. When the transmitter network device 500 transitions from the power-down state to the power-up state, the transmitter network device 500 may still not require a clock to operate. For example, during initialization or when the transmitter network device 500 is ready to start without clocking, there is no input data from the 32:4 serializer 506. In this state, OUTP=1 and OUTN=1, indicating both the positive and negative output signals are set to one (1). This could be part of the initialization or power-up process before data transmission begins.

In yet further embodiments, as an additional step of the power-up process, the transmitter network device 500 may transition the termination circuit 524 from the power-down state to the power-up state after the configurable time period following the transition of the CML driver circuit 520 from the power-down state to the power-up state. The transmitter network device 500 may actuate the third switch 530 and the fourth switch 532 to transition the termination circuit 524 from the power-down state to the power-up state. The third switch 530 and the fourth switch 532 may be actuated to a closed state, causing the termination circuit 524 to be activated. In yet several more embodiments, the termination circuit 524 is transitioned to the power-up state shortly after the CML driver circuit 520 is transitioned to the power-up state, to prevent the CML driver current from discharging common mode of the termination circuit 524 output. In yet many additional embodiments, the transmitter network device 500 may be configured to disable the CM keeper circuit 504 following the transition of the termination circuit 524 to the power-up state. To disable the CM keeper circuit 504, the transmitter network device 500 may actuate the fifth switch 534 and the sixth switch 536 to decouple the CM keeper circuit 504 from the one or more output terminals of the SerDes circuit 502. As a result, the output of the termination circuit 524 to +127 code triggering signal detection by a receiver device.

In still yet various embodiments, as a further step of the power-up process, the transmitter network device 500 may actuate the second switch 528 to transition the clock fan-up circuit 516 from the power-down state to the power-up state. The second switch 528 may be actuated to a closed state, causing the clock fan-up circuit 516 to be activated to prevent large current delta on the V_{DDM}. In yet many further embodiments, the transmitter network device 500 may flip the termination circuit 524 to −128 code to keep DC balance. Further, the transmitter network device 500 may apply C8 data pattern via a datapath of the termination circuit 524 to enable rapid Clock Data Recovery (CDR) lock.

According to one or more embodiments, when data becomes available for transmission, the circuit elements of the SerDes circuit 502 can be quickly powered up, restoring full operational capacity without delay. Further, by maintaining the output voltage of the SerDes circuit 502 at the configured level, the CM keeper circuit 504 ensures that the SerDes circuit 502 is ready to quickly and reliably recover when powered back on, minimizing any delay or issues during reactivation and ensuring smooth, continuous operation.

Although, it has been described above that the phase interpolator 514, the clock fan-up circuit 516, the termination circuit 524, and the CML driver circuit 520 are transitioned from the power-down state to the power-up state in a specific sequence, in many more embodiments, the phase interpolator 514, the clock fan-up circuit 516, the termination circuit 524, and the CML driver circuit 520 may be transitioned from the power-down state to the power-up state in a staggered sequence.

Aspects of the present disclosure improve power management in the transmitter network device 500 by selectively deactivating specific circuit elements to reduce power consumption. The power management strategy may ensure substantial energy savings during periods of inactivity or low data transmission, thereby lowering overall power usage. Additionally, overvoltage conditions are mitigated by carefully regulating the output voltage of the SerDes circuit 502 when the current source of the CML driver circuit 520 is deactivated. Furthermore, common-mode voltage fluctuations, which could destabilize the transmitter network device 500, especially in AC or DC coupled configurations, are effectively managed. By controlling the common-mode voltage fluctuations, the transmitter network device 500 may maintain stability and reliable operation in high-speed environments. The method of gating the differential inputs of the CML driver circuit 520 facilitates a controlled shutdown of the CML driver circuit 520, enhancing power efficiency while preserving circuit functionality. This approach also contributes to prolonging the lifespan of the transmitter network device 500 by minimizing unnecessary power consumption and preventing potential overvoltage-related damage.

Although a specific embodiment for the configuration of the transmitter network device 500 when data is absent for transmission is described above with respect to FIG. 5, any of a variety of systems and/or processes may be utilized in accordance with embodiments of the disclosure. For example, a receiver network device may function in a similar way as the transmitter network device 500 when data is absent for transmission. The elements depicted in FIG. 5 may also be interchangeable with other elements of FIGS. 1-4 and 6-21 as required to realize a particularly desired embodiment.

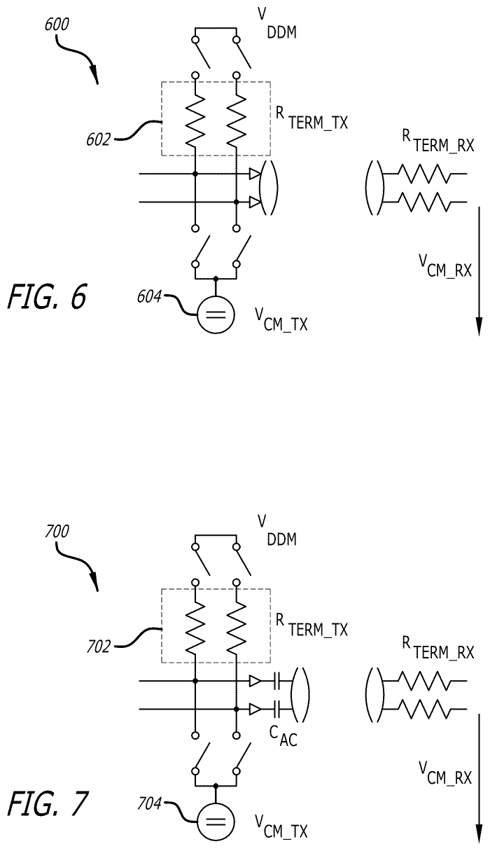

Referring to FIG. 6, a circuit diagram 600 of a Common Mode (CM) keeper circuit 604 for Direct Current (DC) coupled Serializer/Deserializer (SerDes) circuit in accordance with various embodiments of the disclosure is shown. In FIG. 6, a termination circuit 602 and a CM keeper circuit 604 are shown. In many embodiments, the CM keeper circuit 604 may maintain common mode voltage (that may be an output of the termination circuit 602) at a configured level in an OFF state. According to various embodiments, the CM keeper circuit 604 may prevent RX common mode termination cap Cₜₑᵣₘ_{_{RX}} from being discharged, where RX represents a receiver.

Although a specific embodiment for the circuit diagram of the CM keeper circuit 604 for DC coupled SerDes circuit is described above with respect to FIG. 6, any of a variety of systems and/or processes may be utilized in accordance with embodiments of the disclosure. For example, the CM keeper circuit 604 may operate in a different manner when connected to Alternating Current (AC) coupled SerDes circuit. The elements depicted in FIG. 6 may also be interchangeable with other elements of FIGS. 1-5 and 7-21 as required to realize a particularly desired embodiment.

Referring to FIG. 7, a circuit diagram 700 of a Common Mode (CM) keeper circuit 704 for AC coupled SerDes circuit in accordance with various embodiments of the disclosure is shown. In FIG. 7, a termination circuit 702 and a CM keeper circuit 704 are shown. In many embodiments, the CM keeper circuit 704 may maintain common mode voltage (that may be an output of the termination circuit 702) at a configured level in an OFF state. According to various embodiments, the CM keeper circuit 704 may prevent inline channel cap C_{AC} and RX common mode termination cap Cₜₑᵣₘ_{_{RX}} from being discharged.

Although a specific embodiment for the circuit diagram of the CM keeper circuit 704 for AC coupled SerDes circuit is described above with respect to FIG. 7, any of a variety of systems and/or processes may be utilized in accordance with embodiments of the disclosure. For example, the CM keeper circuit 704 may operate in a different manner when connected to DC coupled SerDes circuit. The elements depicted in FIG. 7 may also be interchangeable with other elements of FIGS. 1-6 and 8-21 as required to realize a particularly desired embodiment.

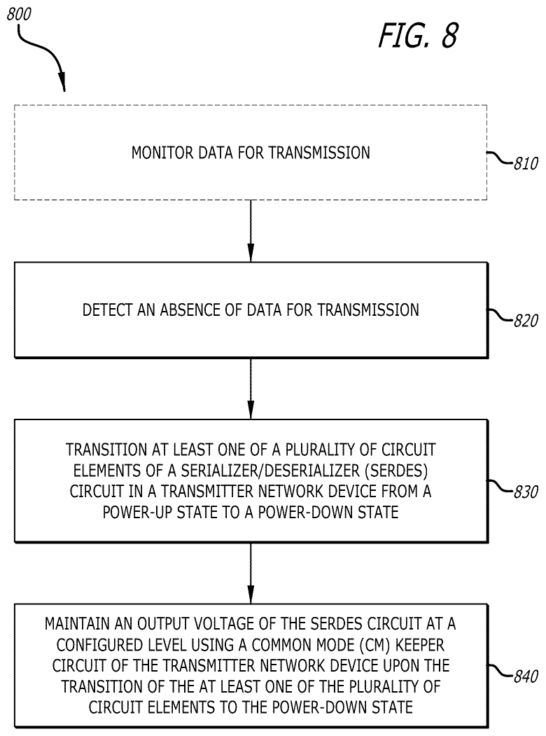

Referring to FIG. 8, a flowchart depicting a process 800 for transitioning at least one of a plurality of circuit elements of a SerDes circuit in a transmitter network device from a power-up state to a power-down state in accordance with various embodiments of the disclosure is shown.

In a number of embodiments, the process 800 may monitor data for transmission (block 810). The process 800 may monitor a communication link associated with a network device for incoming data to be the transmitted. For example, the process 800 may check if the communication link is idle or active by continuously evaluating presence or absence of data signals. In an example, if there is no data to be transmitted for a pre-determined period of time, the process 800 may identify that the communication link is idle. In one or more embodiments, the monitoring of the data for transmission may be optional.

In many embodiments, the process 800 may detect an absence of data for transmission (block 820). The process 800 may detect the absence of data for transmission based on monitoring the data for transmission. In an example, the process 800 may detect the absence of data for transmission if the communication link is identified to be idle for the pre-determined period of time. The communication link may be idle due to low traffic, with no data available to transmit over the communication link during a given period.

In various embodiments, the process 800 may transition at least one of a plurality of circuit elements of a SerDes circuit in a transmitter network device from a power-up state to a power-down state (block 830). In a non-limiting example, the plurality of circuit elements may include two or more of a phase interpolator, a clock fan-up circuit, a CML driver circuit, and a termination circuit. The power-up state may represent an active, high-power mode, and the power-down state may represent a low-power mode, such as a sleep mode. A high-power mode may refer to a state where a circuit element is fully powered and active, utilizing power required to perform functions efficiently. A low-power mode may refer to a state where the power consumption of a circuit element is reduced by deactivating the circuit element.

In yet various embodiments the process 800 may maintain an output voltage of the SerDes circuit at a configured level using a CM keeper circuit of the transmitter network device upon the transition of the at least one of the plurality of circuit elements to the power-down state (block 840). The process 800 may enable the CM keeper circuit based on the transition of the at least one of the plurality of circuit elements to the power-down state. The output voltage of the SerDes circuit may be maintained at the configured level based on the enabling of the CM keeper circuit.

Although a specific embodiment for the process 800 for transitioning at least one of the plurality of circuit elements of the SerDes circuit in the transmitter network device from the power-up state to the power-down state suitable for carrying out the various steps, processes, methods, and operations described herein is discussed with respect to FIG. 8, any of a variety of systems and/or processes may be utilized in accordance with embodiments of the disclosure. For example, the process 800 may generate a power-down signal and transmit the generated power-down signal to a receiver device indicating the power-down state of the at least one of the plurality of circuit elements. The elements depicted in FIG. 8 may also be interchangeable with other elements of FIGS. 1-7 and FIGS. 9-21 as required to realize a particularly desired embodiment.

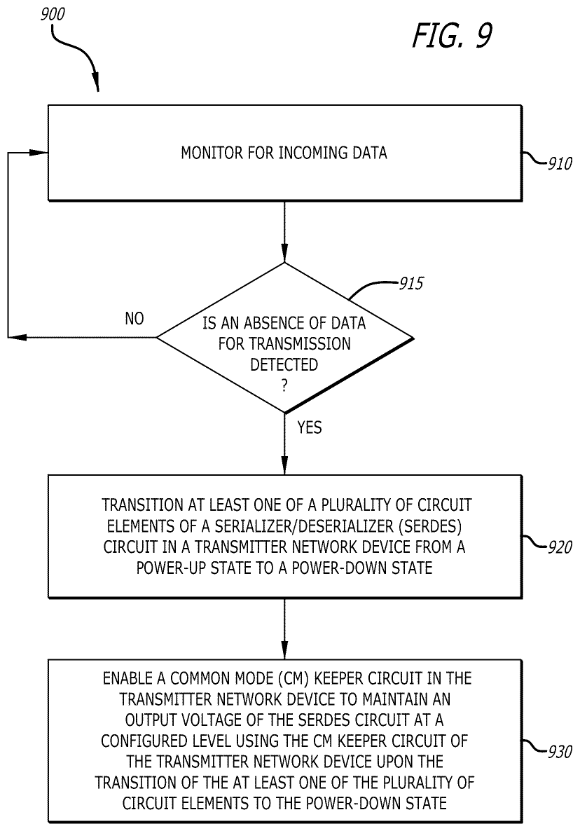

Referring to FIG. 9, a flowchart depicting a process 900 for enabling a CM keeper circuit in a transmitter network device to maintain an output voltage of a SerDes circuit at a configured level in accordance with various embodiments of the disclosure in shown.

In several embodiments, the process 900 may monitor for incoming data (block 910). The process 900 may monitor a communication link associated with a network device for incoming data. For example, the process 900 may check if the communication link is idle or active by continuously evaluating presence or absence of data signals. In an example, if there is no data to be transmitted for a pre-determined period of time, the process 900 may identify that the communication link is idle.

In more embodiments, the process 900 may determine whether an absence of data for transmission is detected (block 915). The process 900 may determine whether an absence of data for transmission is detected based on monitoring the data for transmission. In an example, the process 900 may detect the absence of data for transmission if the communication link is identified to be idle for the pre-determined period of time. The communication link may be idle due to low traffic, with no data available to transmit over the communication link during a given period.

In still more embodiments, if the absence of data for transmission is not detected (i.e., the data is present for transmission), the process 900 may continue to monitor for incoming data (block 910). However, if the absence of data for transmission is detected, the process 900 may transition at least one of a plurality of circuit elements of a SerDes circuit in a transmitter network device from a power-up state to a power-down state (block 920). In a non-limiting example, the plurality of circuit elements may include two or more of a phase interpolator, a clock fan-up circuit, a CML driver circuit, and a termination circuit. In one or more embodiments, the process 900 may transition one of the phase interpolator, the clock fan-up circuit, the CML driver circuit, or the termination circuit from the power-up state to the power-down state.

In further embodiments, the process 900 may enable a CM keeper circuit in the transmitter network device to maintain an output voltage of the SerDes circuit at a configured level using the CM keeper circuit of the transmitter network device upon the transition of the at least one of the plurality of circuit elements to the power-down state (block 930). The process 900 may actuate a switching element between the CM keeper circuit and one or more output terminals of the SerDes circuit. In an example embodiment, the process 900 may actuate the switching element to couple the CM keeper circuit to the one or more output terminals of the SerDes circuit to enable the CM keeper circuit.

Although a specific embodiment for the process 900 for enabling the CM keeper circuit in the transmitter network device to maintain the output voltage of the SerDes circuit at the configured level suitable for carrying out the various steps, processes, methods, and operations described herein is discussed with respect to FIG. 9, any of a variety of systems and/or processes may be utilized in accordance with embodiments of the disclosure. For example, the process 900 may detect a presence of data for transmission, and transition the at least one of the plurality of circuit elements from the power-down state to the power-up state based on the detection of the presence of data for transmission. The elements depicted in FIG. 9 may also be interchangeable with other elements of FIGS. 1-8 and FIGS. 10-21 as required to realize a particularly desired embodiment.

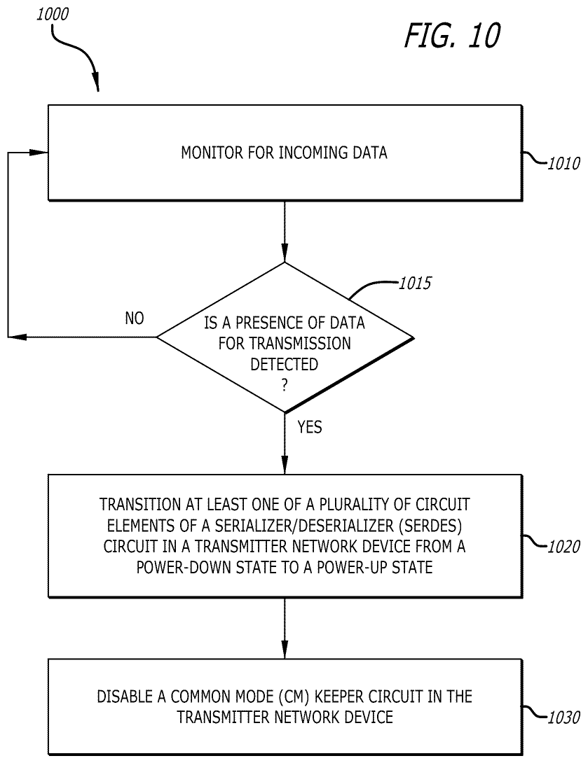

Referring to FIG. 10, a flowchart depicting a process 1000 for disabling a CM keeper circuit in a transmitter network device in accordance with various embodiments of the disclosure is shown. In numerous embodiments, the process 1000 may monitor for incoming data (block 1010). The process 1000 may monitor a communication link associated with a network device for incoming data to be transmitted. For example, the process 1000 may check if the communication link is idle or active by continuously evaluating presence or absence of data signals. In an example, if there is no data to be transmitted for a pre-determined period of time, the process 1000 may identify that the communication link is idle.

In many more embodiments, the process 1000 may determine whether a presence of data for transmission is detected (block 1015). The process 1000 may determine whether a presence of data for transmission is detected based on monitoring the data for transmission. In an example, the process 1000 may detect the presence of data for transmission if the communication link is identified to be active.

In further additional embodiments, if the presence of data for transmission is not detected (i.e., the data absent for transmission), the process 1000 may continue to monitor for incoming data (block 1010). However, if the presence of data for transmission is detected, the process 1000 may transition at least one of a plurality of circuit elements of a SerDes circuit in a transmitter network device from a power-down state to a power-up state (block 1020). In a non-limiting example, the plurality of circuit elements may include two or more of a phase interpolator, a clock fan-up circuit, a CML driver circuit, and a termination circuit. In one or more embodiments, the process 1000 may transition one of the phase interpolator, the clock fan-up circuit, the CML driver circuit, or the termination circuit from the power-down state to the power-up state.

In further embodiments, the process 1000 may disable a CM keeper circuit in the transmitter network device (block 1030). The process 1000 may actuate a switching element between the CM keeper circuit and one or more output terminals of the SerDes circuit. In an example embodiment, the process 1000 may actuate the switching element to decouple the CM keeper circuit from the one or more output terminals of the SerDes circuit to disable the CM keeper circuit.

Although a specific embodiment for the process 1000 for disabling the CM keeper circuit in the transmitter network device suitable for carrying out the various steps, processes, methods, and operations described herein is discussed with respect to FIG. 10, any of a variety of systems and/or processes may be utilized in accordance with embodiments of the disclosure. For example, the process 1000 may generate a power-up signal, and transmit the generated power-up signal to a receiver device indicating the power-up state of the at least one of the plurality of circuit elements. The elements depicted in FIG. 10 may also be interchangeable with other elements of FIGS. 1-9 and FIGS. 11-21 as required to realize a particularly desired embodiment.

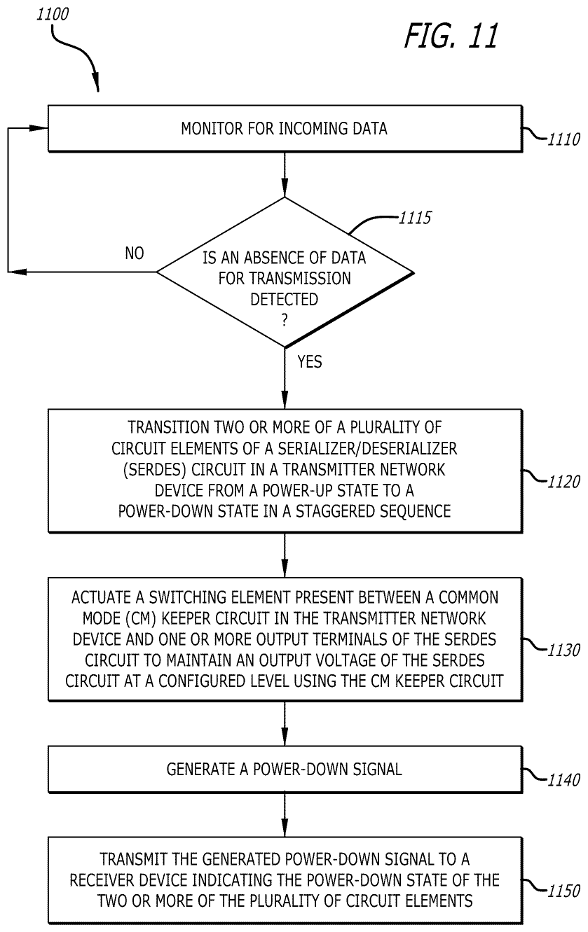

Referring to FIG. 11, a flowchart depicting a process 1100 for transmitting a generated power-down signal to a receiver device indicating a power-down state of two or more of a plurality of circuit elements of a SerDes circuit in accordance with various embodiments of the disclosure is shown.

In additional embodiments, the process 1100 may monitor for incoming data (block 1110). The process 1100 may monitor a communication link associated with a network device for incoming data to be transmitted. For example, the process 1100 may check if the communication link is idle or active by continuously evaluating presence or absence of data signals. In an example, if there is no data to be transmitted for a pre-determined period of time, the process 1100 may identify that the communication link is idle.

In still yet more embodiments, the process 1100 may determine whether an absence of data for transmission is detected (block 1115). The process 1100 may determine whether an absence of data for transmission is detected based on monitoring the data for transmission. In an example, the process 1100 may detect the absence of data for transmission if the communication link is identified to be idle for the pre-determined period of time. The communication link may be idle due to low traffic, with no data available to transmit over the communication link during a given period.

In yet further embodiments, if the absence of data for transmission is not detected (i.e., the data is present for transmission), the process 1100 may continue to monitor for incoming data (block 1110). However, if the absence of data for transmission is detected, the process 1100 may transition two or more of a plurality of circuit elements of a SerDes circuit in a transmitter network device from a power-up state to a power-down state in a staggered sequence (block 1120). In one or more embodiments, the process 1100 may transition the two or more of a plurality of circuit elements of the SerDes circuit from the power-up state to the power-down state in the staggered sequence based on the detection of the absence of data for transmission. According to the staggered sequence, each circuit element may be powered down at different times, depending on operational requirements and current data transmission needs. As a result, overall power consumption of the transmitter network device is reduced.

In yet several more embodiments, the process 1100 may actuate a switching element present between a CM keeper circuit in the transmitter network device and one or more output terminals of the SerDes circuit to maintain an output voltage of the SerDes circuit at a configured level using the CM keeper circuit (block 1130). The process 1100 may actuate the switching element to couple the CM keeper circuit to the SerDes circuit. In examples, maintaining of the output voltage of the SerDes circuit at the configured level may be based on the CM keeper circuit being coupled to the one or more output terminals. The process 1100 may enable the CM keeper circuit based on actuating the switching element.

In yet many additional embodiments, the process 1100 may generate a power-down signal (block 1140). The process 1100 may generate the power-down signal to indicate the power-down state of the two or more of the plurality of circuit elements. The purpose of the power-down signal may be to notify a receiver device to enter a power-down state in order to conserve energy.

In still yet various embodiments, the process 1100 may transmit the generated power-down signal to a receiver device indicating the power-down state of the two or more of the plurality of circuit elements (block 1150). The process 1100 may transmit the generated power-down signal via a communication interface. The receiver device may transition two or more of a plurality of circuit elements of a SerDes circuit in the receiver device from a power-up state to a power-down state. In an example, the receiver device may transition the two or more of the plurality of circuit elements of the SerDes circuit from the power-up state to the power-down state in a staggered sequence.

Although a specific embodiment for the process 1100 for transmitting the generated power-down signal to the receiver device indicating the power-down state of the two or more of the plurality of circuit elements of the SerDes circuit suitable for carrying out the various steps, processes, methods, and operations described herein is discussed with respect to FIG. 11, any of a variety of systems and/or processes may be utilized in accordance with embodiments of the disclosure. For example, the process 1100 may generate a power-up signal and send the power-up signal to the receiver device indicating a power-up state of the two or more of the plurality of circuit elements. The elements depicted in FIG. 9 may also be interchangeable with other elements of FIGS. 1-10 and FIGS. 12-21 as required to realize a particularly desired embodiment.

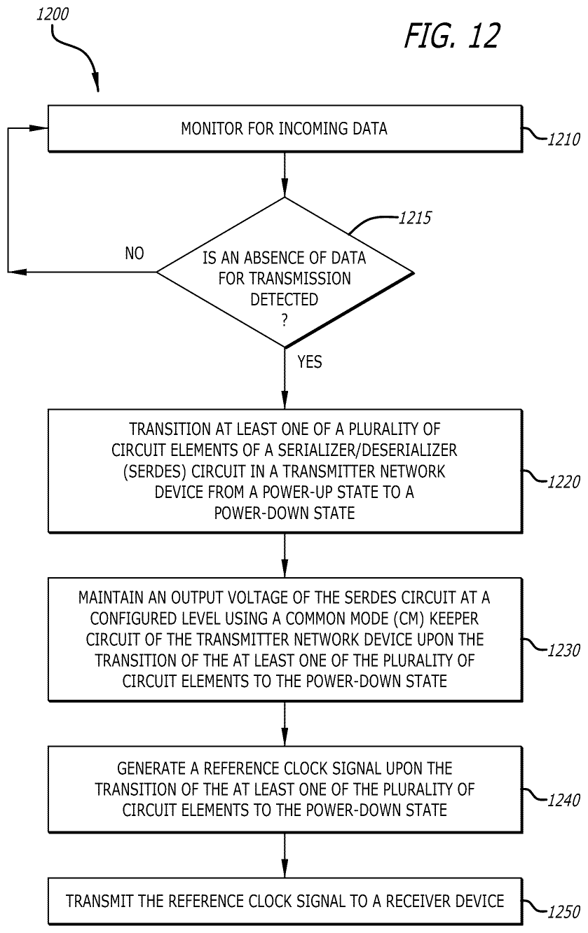

Referring to FIG. 12, a flowchart depicting a process 1200 for transmitting a reference clock signal to a receiver device in accordance with various embodiments of the disclosure is shown. In several embodiments, the process 1200 may monitor for incoming data (block 1210). The process 1200 may monitor a communication link associated with a network device for incoming data to be the transmitted. For example, the process 1200 may check if the communication link is idle or active by continuously evaluating presence or absence of data signals. In an example, if there is no data to be transmitted for a pre-determined period of time, the process 1200 may identify that the communication link is idle.

In more embodiments, the process 1200 may determine whether an absence of data for transmission is detected (block 1215). The process 1200 may determine whether an absence of data for transmission is detected based on monitoring the incoming data. In an example, the process 1200 may detect the absence of data for transmission if the communication link is identified to be idle for the pre-determined period of time. The communication link may be idle due to low traffic, with no data available to transmit over the communication link during a given period.

In still more embodiments, if the absence of data for transmission is not detected (i.e., the data is present for transmission), the process 1200 may continue to monitor for incoming data (block 1210). However, if the absence of data for transmission is detected, the process 1200 may transition at least one of a plurality of circuit elements of a SerDes circuit in a transmitter network device from a power-up state to a power-down state (block 1220). In a non-limiting example, the plurality of circuit elements may include two or more of a phase interpolator, a clock fan-up circuit, a CML driver circuit, and a termination circuit. In one or more embodiments, the process 1200 may transition one of the phase interpolator, the clock fan-up circuit, the CML driver circuit, or the termination circuit from the power-up state to the power-down state.

In further embodiments, the process 1200 may maintain an output voltage of the SerDes circuit at a configured level using a CM keeper circuit of the transmitter network device upon the transition of the at least one of the plurality of circuit elements to the power-down state (block 1230). The process 1200 may enable the CM keeper circuit based on the transition of the at least one of the plurality of circuit elements to the power-down state. The output voltage of the SerDes circuit may be maintained at the configured level based on the enabling of the CM keeper circuit.

In still more embodiments, the process 1200 may generate a reference clock signal upon the transition of the at least one of the plurality of circuit elements to the power-down state (1240). The process 1200 may generate the reference clock signal for a receiver device. In an example, the reference clock signal may ensure that the timing of the receiver device remains aligned with the transmitter network device, particularly with respect to a start time of the power-down state of the at least one of the plurality of circuit elements.

In some more embodiments, the process 1200 may transmit the reference clock signal to a receiver device (block 1250). The process 1200 may transmit the reference clock signal to the receiver device via a communication interface. In further embodiments, the receiver device may receive the reference clock signal from the transmitter network device. The receiver device may then maintain a timing alignment with the transmitter network device during the power-down state based on the received reference clock signal.

Although a specific embodiment for the process 1200 for transmitting the reference clock signal to the receiver device suitable for carrying out the various steps, processes, methods, and operations described herein is discussed with respect to FIG. 12, any of a variety of systems and/or processes may be utilized in accordance with embodiments of the disclosure. For example, the process 1200 may transmit a reference clock signal to the receiver device upon transition of at least one of the plurality of circuit elements to a power-up state. The elements depicted in FIG. 12 may also be interchangeable with other elements of FIGS. 1-11 and FIGS. 13-21 as required to realize a particularly desired embodiment.

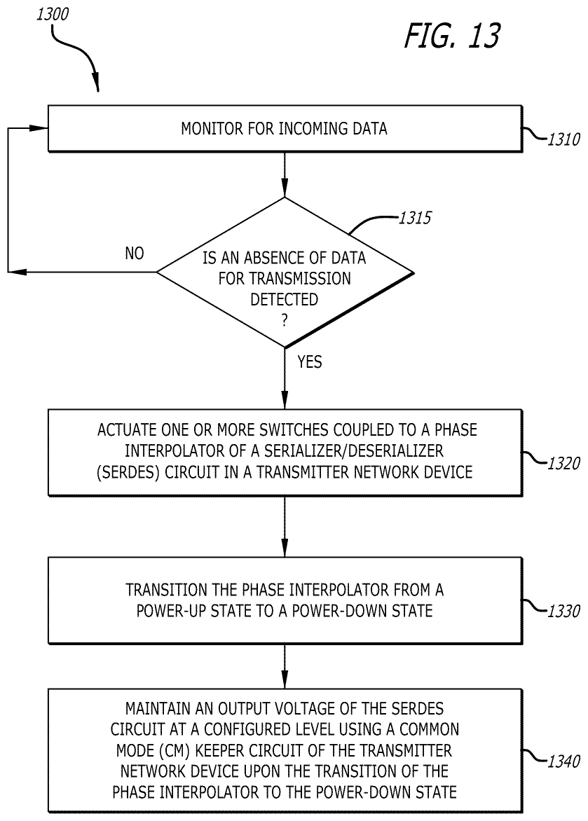

Referring to FIG. 13, a flowchart depicting a process 1300 for transitioning a phase interpolator of a SerDes circuit from a power-up state to a power-down state in accordance with various embodiments of the disclosure is shown. In many embodiments, the process 1300 may monitor for incoming data (block 1310). The process 1300 may monitor a communication link associated with a network device for incoming data to be the transmitted. For example, the process 1300 may check if the communication link is idle or active by continuously evaluating presence or absence of data signals. In an example, if there is no data to be transmitted for a pre-determined period of time, the process 1300 may identify that the communication link is idle.

In many further embodiments, the process 1300 may determine whether an absence of data for transmission is detected (block 1315). The process 1300 may determine whether an absence of data for transmission is detected based on monitoring the incoming data. In an example, the process 1300 may detect the absence of data for transmission if the communication link is identified to be idle for the pre-determined period of time. The communication link may be idle due to low traffic, with no data available to transmit over the communication link during a given period.

In yet more embodiments, if the absence of data for transmission is not detected (i.e., the data is present for transmission), the process 1300 may continue to monitor for incoming data (block 1310). However, if the absence of data for transmission is detected, the process 1300 may actuate one or more switches coupled to a phase interpolator of a SerDes circuit in the transmitter network device (block 1320). In an example, the one or more switches may be connected to a power source. The process 1300 may actuate the one or more switches to an open state, causing the phase interpolator to be deactivated, and thus preventing the phase interpolator from consuming power.

In still various embodiments, the process 1300 may transition the phase interpolator from a power-up state to a power-down state (block 1330). The phase interpolator may be transitioned from the power-up state to the power-down state based on actuating one or more switches coupled to the phase interpolator. By transitioning the phase interpolator to the power-down state, power consumption is reduced while ensuring that the phase interpolator can quickly return to an operational state.

In further embodiments, the process 1300 may maintain an output voltage of the SerDes circuit at a configured level using a CM keeper circuit of the transmitter network device upon the transition of the phase interpolator to the power-down state (block 1340). The process 1300 may enable the CM keeper circuit based on the transition of the phase interpolator to the power-down state. The output voltage of the SerDes circuit may be maintained at the configured level based on the enabling of the CM keeper circuit.

Although a specific embodiment for the process 1300 for transitioning the phase interpolator of the SerDes circuit from the power-up state to the power-down state suitable for carrying out the various steps, processes, methods, and operations described herein is discussed with respect to FIG. 13, any of a variety of systems and/or processes may be utilized in accordance with embodiments of the disclosure. For example, the process 1300 may transition the phase interpolator of the SerDes circuit from the power-down state to the power-up state when presence of data for transmission is detected. The elements depicted in FIG. 13 may also be interchangeable with other elements of FIGS. 1-12 and FIGS. 14-21 as required to realize a particularly desired embodiment.

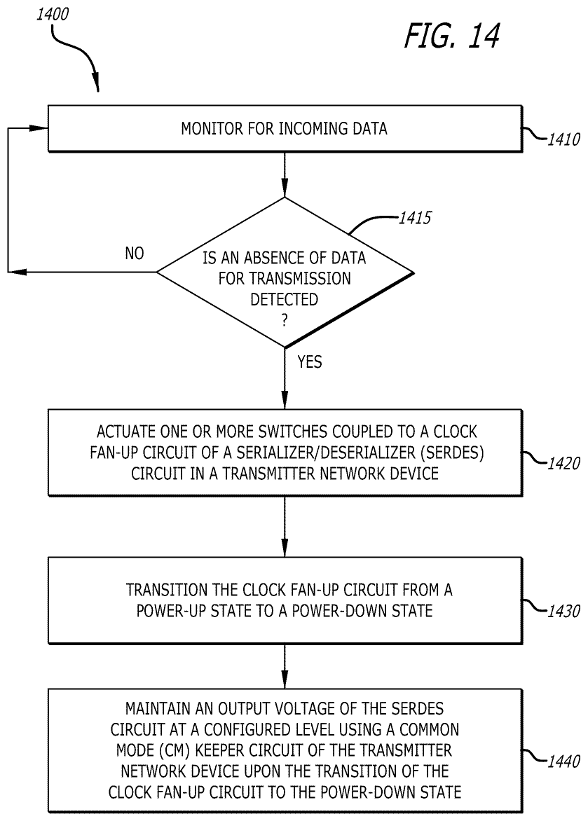

Referring to FIG. 14, a flowchart depicting a process 1400 for transitioning a clock fan-up circuit of a SerDes circuit from a power-up state to a power-down state in accordance with various embodiments of the disclosure is shown. In several embodiments, the process 1400 may monitor for incoming data (block 1410). The process 1400 may monitor a communication link associated with a network device for incoming data to be the transmitted. For example, the process 1400 may check if the communication link is idle or active by continuously evaluating presence or absence of data signals. In an example, if there is no data to be transmitted for a pre-determined period of time, the process 1400 may identify that the communication link is idle.

In additional embodiments, the process 1400 may determine whether an absence of data for transmission is detected (block 1415). The process 1400 may determine whether an absence of data for transmission is detected based on monitoring the incoming data. In an example, the process 1400 may detect the absence of data for transmission if the communication link is identified to be idle for the pre-determined period of time. The communication link may be idle due to low traffic, with no data available to transmit over the communication link during a given period.

In still yet more embodiments, if the absence of data for transmission is not detected (i.e., the data is present for transmission), the process 1400 may continue to monitor for incoming data (block 1410). However, if the absence of data for transmission is detected, the process 1400 may actuate one or more switches coupled to a clock fan-up circuit of a SerDes circuit in the transmitter network device (block 1420). In an example, the one or more switches may be connected to a power source. The process 1400 may actuate the one or more switches to an open state, causing the clock fan-up circuit to be deactivated, and thus preventing the clock fan-up circuit from consuming power.

In yet several more embodiments, the process 1400 may transition the clock fan-up circuit from a power-up state to a power-down state (block 1430). The clock fan-up circuit may be transitioned from the power-up state to the power-down state based on actuating one or more switches coupled to the clock fan-up circuit. By transitioning the clock fan-up circuit to the power-down state, power consumption is reduced while ensuring that the clock fan-up circuit can quickly return to an operational state.

In yet many additional embodiments, the process 1400 may maintain an output voltage of the SerDes circuit at a configured level using a CM keeper circuit of the transmitter network device upon the transition of the clock fan-up circuit to the power-down state (block 1440). The process 1400 may enable the CM keeper circuit based on the transition of the clock fan-up circuit to the power-down state. The output voltage of the SerDes circuit may be maintained at the configured level based on the enabling of the CM keeper circuit.

Although a specific embodiment for the process 1400 for transitioning the clock fan-up circuit of the SerDes circuit from the power-up state to the power-down state suitable for carrying out the various steps, processes, methods, and operations described herein is discussed with respect to FIG. 14, any of a variety of systems and/or processes may be utilized in accordance with embodiments of the disclosure. For example, the process 1400 may transition the clock fan-up circuit of the SerDes circuit from the power-down state to the power-up state when presence of data for transmission is detected. The elements depicted in FIG. 13 may also be interchangeable with other elements of FIGS. 1-13 and FIGS. 15-21 as required to realize a particularly desired embodiment.

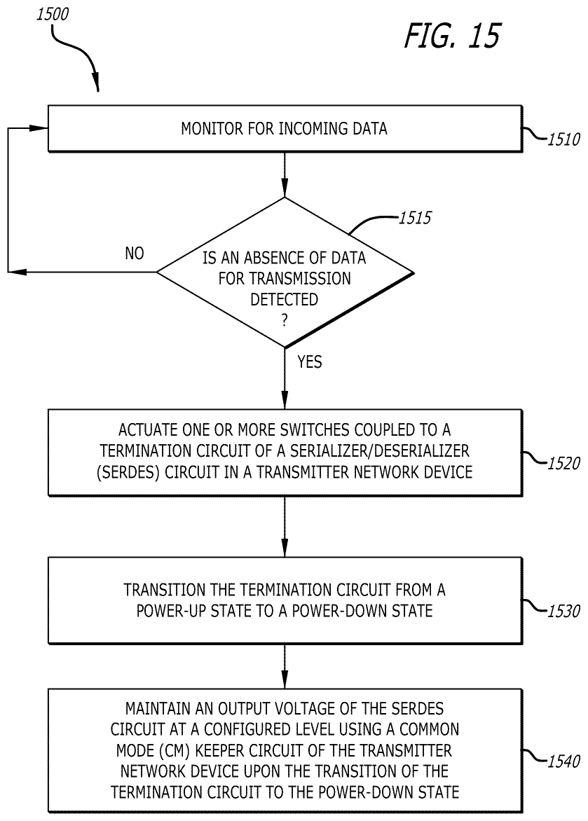

Referring to FIG. 15, a flowchart depicting a process 1500 for transitioning a termination circuit of a SerDes circuit from a power-up state to a power-down state in accordance with various embodiments of the disclosure is shown. In further embodiments, the process 1500 may monitor for incoming data (block 1510). The process 1500 may monitor a communication link associated with a network device for incoming data to be the transmitted. For example, the process 1500 may check if the communication link is idle or active by continuously evaluating presence or absence of data signals. In an example, if there is no data to be transmitted for a pre-determined period of time, the process 1500 may identify that the communication link is idle.

In further additional embodiments, the process 1500 may determine whether an absence of data for transmission is detected (block 1515). The process 1500 may determine whether an absence of data for transmission is detected based on monitoring the incoming data. In an example, the process 1500 may detect the absence of data for transmission if the communication link is identified to be idle for the pre-determined period of time. The communication link may be idle due to low traffic, with no data available to transmit over the communication link during a given period.

In additional embodiments, if the absence of data for transmission is not detected (i.e., the data is present for transmission), the process 1500 may continue to monitor for incoming data (block 1510). However, if the absence of data for transmission is detected, the process 1500 may actuate one or more switches coupled to a termination circuit of a SerDes circuit in the transmitter network device (block 1520). In an example, the one or more switches may be connected to a power source. The process 1500 may actuate the one or more switches to an open state, causing the termination circuit to be deactivated, and thus preventing the termination circuit from consuming power.

In yet more embodiments, the process 1500 may transition the termination circuit from a power-up state to a power-down state (block 1530). The termination circuit may be transitioned from the power-up state to the power-down state based on actuating one or more switches coupled to the termination circuit. By transitioning the termination circuit to the power-down state, power consumption is reduced while ensuring that the termination circuit can quickly return to an operational state.

In many further embodiments, the process 1500 may maintain an output voltage of the SerDes circuit at a configured level using a CM keeper circuit of the transmitter network device upon the transition of the termination circuit to the power-down state (block 1540). The process 1500 may enable the CM keeper circuit based on the transition of the termination circuit to the power-down state. The output voltage of the SerDes circuit may be maintained at the configured level based on the enabling of the CM keeper circuit.

Although a specific embodiment for the process 1500 for transitioning the termination circuit of the SerDes circuit from the power-up state to the power-down state suitable for carrying out the various steps, processes, methods, and operations described herein is discussed with respect to FIG. 15, any of a variety of systems and/or processes may be utilized in accordance with embodiments of the disclosure. For example, the process 1500 may transition the termination circuit of the SerDes circuit from the power-down state to the power-up state when presence of data for transmission is detected. The elements depicted in FIG. 15 may also be interchangeable with other elements of FIGS. 1-14 and FIGS. 16-21 as required to realize a particularly desired embodiment.

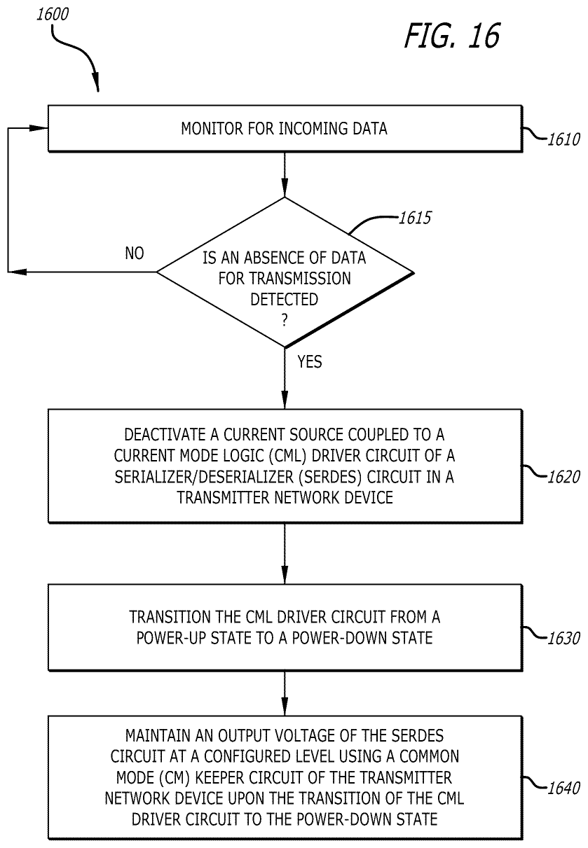

Referring to FIG. 16, a flowchart depicting a process 1600 for transitioning a CML driver circuit of a SerDes circuit from a power-up state to a power-down state in accordance with various embodiments of the disclosure is shown.

In a number of embodiments, the process 1600 may monitor for incoming data (block 1610). The process 1600 may monitor a communication link associated with a network device for incoming data to be the transmitted. For example, the process 1600 may check if the communication link is idle or active by continuously evaluating presence or absence of data signals. In an example, if there is no data to be transmitted for a pre-determined period of time, the process 1600 may identify that the communication link is idle.

In many embodiments, the process 1600 may determine whether an absence of data for transmission is detected (block 1615). The process 1600 may determine whether an absence of data for transmission is detected based on monitoring the incoming data. In an example, the process 1600 may detect the absence of data for transmission if the communication link is identified to be idle for the pre-determined period of time. The communication link may be idle due to low traffic, with no data available to transmit over the communication link during a given period.

In various embodiments, if the absence of data for transmission is not detected (i.e., the data is present for transmission), the process 1600 may continue to monitor for incoming data (block 1610). However, if the absence of data for transmission is detected, the process 1600 may deactivate a current source coupled to a CML driver circuit of a SerDes circuit in a transmitter network device (block 1620). In an example, the process 1600 may deactivate the current source coupled to the CML driver circuit based on detecting an absence of data for transmission. The CML driver circuit may include a pair of differential input terminals. The process 1600 may control a gating of the pair of differential input terminals of the CML driver circuit. The deactivation of the current source may be based on the gating of the pair of differential input terminals.

In yet various embodiments, the process 1600 may transition the CML driver circuit from a power-up state to a power-down state (block 1630). The CML driver circuit may be transitioned from the power-up state to the power-down state based on deactivating the current source coupled to the CML driver circuit. By transitioning the CML driver circuit to the power-down state, power consumption by the CML driver circuit is reduced while ensuring that the CML driver circuit can quickly return to an operational state.

In several embodiments, the process 1600 may maintain an output voltage of the SerDes circuit at a configured level using a CM keeper circuit of the transmitter network device upon the transition of the CML driver circuit to the power-down state (block 1640). The process 1600 may enable the CM keeper circuit based on the transition of the CML driver circuit to the power-down state. The output voltage of the SerDes circuit may be maintained at the configured level based on the enabling of the CM keeper circuit.

Although a specific embodiment for the process 1600 for transitioning the CML driver circuit of the SerDes circuit from the power-up state to the power-down state suitable for carrying out the various steps, processes, methods, and operations described herein is discussed with respect to FIG. 16, any of a variety of systems and/or processes may be utilized in accordance with embodiments of the disclosure. For example, the process 1600 may transition the CML driver circuit of the SerDes circuit from the power-down state to the power-up state when presence of data for transmission is detected. The elements depicted in FIG. 16 may also be interchangeable with other elements of FIGS. 1-15 and FIGS. 17-21 as required to realize a particularly desired embodiment.

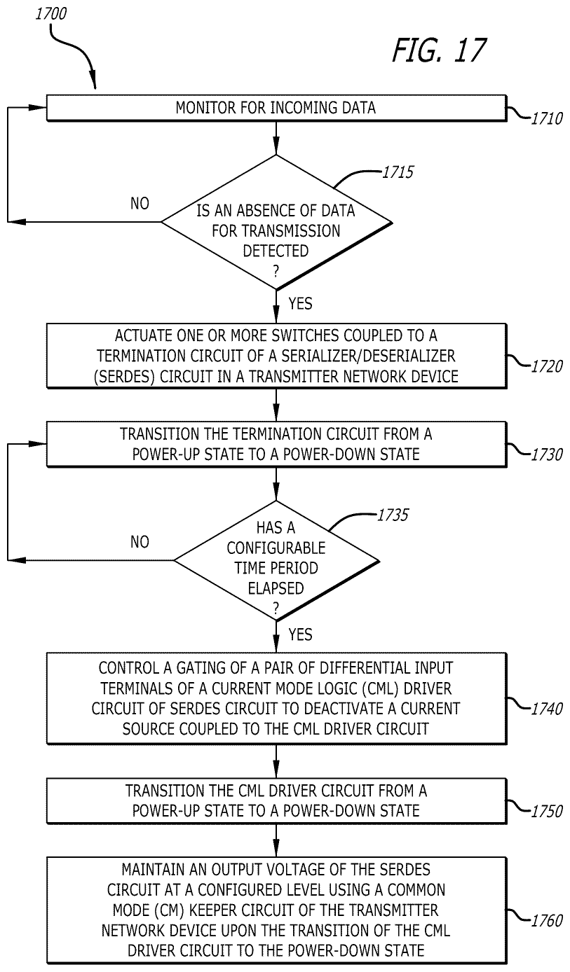

Referring to FIG. 17, a flowchart depicting a process 1700 for controlling a gating of a pair of differential input terminals of a CML driver circuit of SerDes circuit to deactivate a current source coupled to the CML driver circuit in accordance with various embodiments of the disclosure is shown.

In further embodiments, the process 1700 may monitor for incoming data (block 1710). The process 1700 may monitor a communication link associated with a network device for incoming data to be the transmitted. For example, the process 1700 may check if the communication link is idle or active by continuously evaluating presence or absence of data signals. In an example, if there is no data to be transmitted for a pre-determined period of time, the process 1700 may identify that the communication link is idle.

In further additional embodiments, the process 1700 may determine whether an absence of data for transmission is detected (block 1715). The process 1700 may determine whether an absence of data for transmission is detected based on monitoring the incoming data. In an example, the process 1700 may detect the absence of data for transmission if the communication link is identified to be idle for the pre-determined period of time. The communication link may be idle due to low traffic, with no data available to transmit over the communication link during a given period.

In additional embodiments, if the absence of data for transmission is not detected (i.e., the data is present for transmission), the process 1700 may continue to monitor for incoming data (block 1710). However, if the absence of data for transmission is detected, the process 1700 may actuate one or more switches coupled to a termination circuit of a SerDes circuit in the transmitter network device (block 1720). In an example, the one or more switches may be connected to a power source. The process 1700 may actuate the one or more switches to an open state, causing the termination circuit to be deactivated, and thus preventing the termination circuit from consuming power.

In yet more embodiments, the process 1700 may transition the termination circuit from a power-up state to a power-down state (block 1730). The termination circuit may be transitioned from the power-up state to the power-down state based on actuating one or more switches coupled to the termination circuit. By transitioning the termination circuit to the power-down state, power consumption is reduced while ensuring that the termination circuit can quickly return to an operational state.

In several more embodiments, the process 1700 may determine whether a configurable time period has elapsed (block 1735). In an example, the configurable time period may be a time period during which supplying current to a CML driver circuit is maintained. In a non-limiting example, the configurable time period may be in a range of 70 picosecond to 100 picosecond.

In several additional embodiments, in response to determining that the configurable time period has not elapsed, the process 1700 may continue to transition the termination circuit from the power-up state to the power-down state (block 1730). In numerous embodiments, in response to determining that the configurable time period has elapsed, the process 1700 may control a gating of a pair of differential input terminals of the CML driver circuit of SerDes circuit to deactivate a current source coupled to the CML driver circuit (block 1740). In many more embodiments, the process 1700 may deactivate the current source after the configurable time period has elapsed to turn OFF the current flowing through the CML driver circuit. This may be done following the transition of the termination circuit from the power-up state to the power-down state.

In yet various embodiments, the process 1700 may transition the CML driver circuit from a power-up state to a power-down state (block 1750). The CML driver circuit may be transitioned from the power-up state to the power-down state based on deactivating the current source coupled to the CML driver circuit. By transitioning the CML driver circuit to the power-down state, power consumption by the CML driver circuit is reduced while ensuring that the CML driver circuit can quickly return to an operational state when powered ON.

In several embodiments, the process 1700 may maintain an output voltage of the SerDes circuit at a configured level using a CM keeper circuit of the transmitter network device upon the transition of the CML driver circuit to the power-down state (block 1760). The process 1700 may enable the CM keeper circuit based on the transition of the CML driver circuit to the power-down state. The output voltage of the SerDes circuit may be maintained at the configured level based on the enabling of the CM keeper circuit.

Although a specific embodiment for the process 1700 for controlling a gating of a pair of differential input terminals of a CML driver circuit of SerDes circuit to deactivate a current source coupled to the CML driver circuit suitable for carrying out the various steps, processes, methods, and operations described herein is discussed with respect to FIG. 17, any of a variety of systems and/or processes may be utilized in accordance with embodiments of the disclosure. For example, the process 1700 may transition the CML driver circuit of the SerDes circuit from the power-down state to the power-up state when presence of data for transmission is detected. The elements depicted in FIG. 17 may also be interchangeable with other elements of FIGS. 1-16 and FIGS. 18-21 as required to realize a particularly desired embodiment.

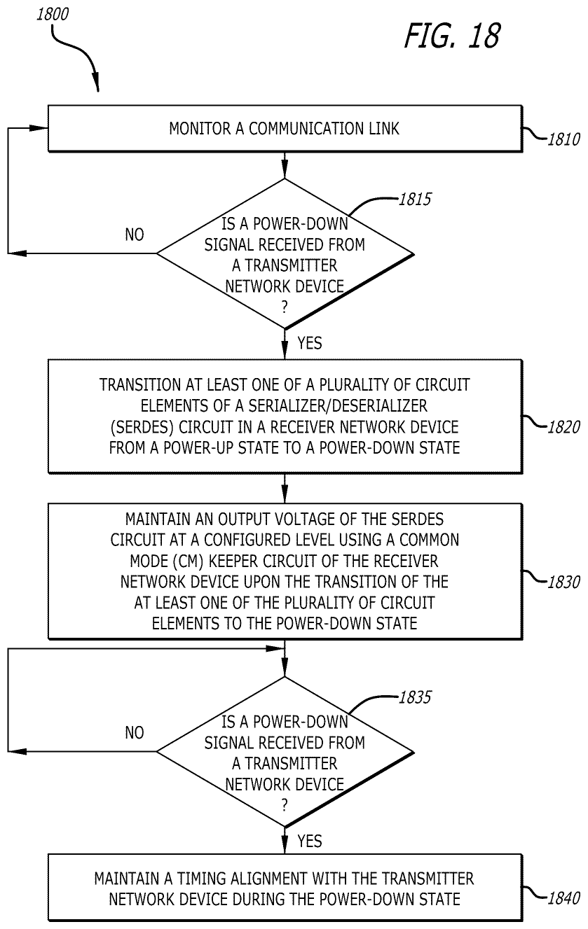

Referring to FIG. 18, a flowchart depicting a process 1800 for maintaining a timing alignment between a receiver network device and a transmitter network device during a power-down state in accordance with various embodiments of the disclosure is shown.

In many embodiments, the process 1800 may monitor a communication link (block 1810). The process 1800 may monitor the communication link for incoming data. For example, the process 1800 may monitor the communication link for one or more signals from a transmitter network device. In an example, the one or more signals may include a power-down signal.

In yet several more embodiments, the process 1800 may determine whether a power-down signal is received (block 1815). The process 1800 may determine whether the power-down signal is received from a transmitter network device. In examples, the power-down signal may indicate a power-down state of two or more of a plurality of circuit elements of a SerDes circuit of the transmitter network device.

In yet many additional embodiments, if it is determined that the power-down signal is not received, the process 1800 may continue to monitor the communication link (block 1810). However, if it is determined that the power-down signal is received, the process 1800 may transition at least one of a plurality of circuit elements of a SerDes circuit in a receiver network device from a power-up state to a power-down state (block 1820). In a non-limiting example, the plurality of circuit elements may include two or more of a phase interpolator, a clock fan-up circuit, a CML driver circuit, and a termination circuit. The power-up state may represent an active, high-power mode, and the power-down state may represent a low-power mode, such as a sleep mode. A high-power mode may refer to a state where a circuit element is fully powered and active, utilizing power required to perform functions efficiently. A low-power mode may refer to a state where the power consumption of a circuit element is reduced by deactivating the circuit element.

In still yet various embodiments, the process 1800 may maintain an output voltage of the SerDes circuit at a configured level using a CM keeper circuit of the receiver network device upon the transition of the at least one of the plurality of circuit elements to the power-down state (block 1830). The process 1800 may enable the CM keeper circuit based on the transition of the at least one of the plurality of circuit elements to the power-down state. The output voltage of the SerDes circuit may be maintained at the configured level based on the enabling of the CM keeper circuit.

In yet many further embodiments, the process 1800 may determine whether a reference clock signal is received from the transmitter network device (block 1835). The process 1800 may determine if the reference clock signal has been received from the transmitter network device upon the transition of the at least one of the plurality of circuit elements to the power-down state. In an example, the reference clock signal may ensure that the timing of the receiver network device remains aligned with the transmitter network device, particularly with respect to a start time of the power-down state of the at least one of the plurality of circuit elements.

In numerous embodiments, if it is determined that the reference clock signal is not received from the transmitter network device, the process 1800 may continue to determine whether the reference clock signal is received from the transmitter network device (block 1835). On the contrary, if it is determined that the reference clock signal has been received from the transmitter network device, the process 1800 may maintain a timing alignment with the transmitter network device during the power-down state (block 1840). In an example, the process 1800 may receive the reference clock signal from the transmitter network device via a communication interface. The receiver device may then maintain a timing alignment with the transmitter network device during the power-down state based on the received reference clock signal.

Although a specific embodiment for the process 1800 for maintaining the timing alignment between the receiver network device and the transmitter network device during the power-down state suitable for carrying out the various steps, processes, methods, and operations described herein is discussed with respect to FIG. 18, any of a variety of systems and/or processes may be utilized in accordance with embodiments of the disclosure. For example, the process 1800 may also maintain the timing alignment between the receiver network device and the transmitter network device during a power-up state. The elements depicted in FIG. 18 may also be interchangeable with other elements of FIGS. 1-17 and FIGS. 18-21 as required to realize a particularly desired embodiment.

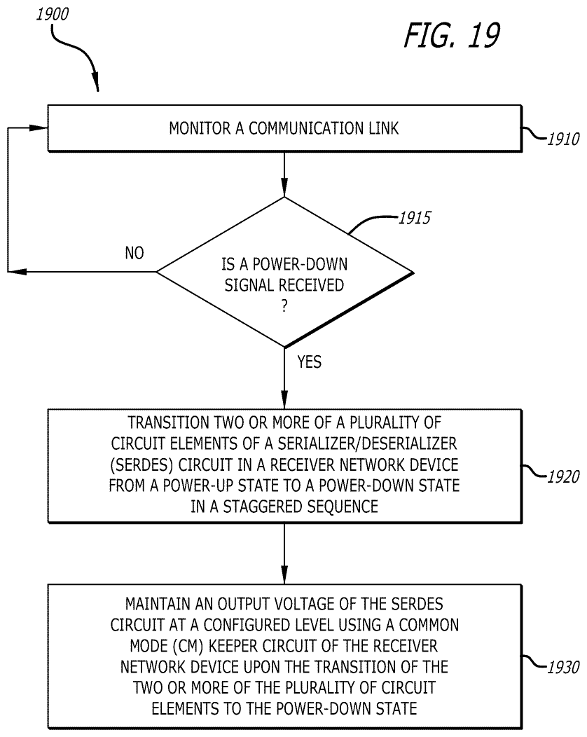

Referring to FIG. 19, a flowchart depicting a process 1900 for transitioning two or more of a plurality of circuit elements of a SerDes circuit in a receiver network device from a power-up state to a power-down state in a staggered sequence in accordance with various embodiments of the disclosure is shown.

In several embodiments, the process 1900 may monitor a communication link (block 1910). The process 1900 may monitor the communication link for incoming data. For example, the process 1900 may monitor the communication link for one or more signals from a transmitter network device. In an example, the one or more signals may include a power-down signal.

In some more embodiments, the process 1900 may determine whether a power-down signal is received (block 1915). The process 1900 may determine whether the power-down signal is received from a transmitter network device. In examples, the power-down signal may indicate a power-down state of two or more of a plurality of circuit elements of a SerDes circuit of the transmitter network device.

In further more embodiments, if it is determined that the power-down signal is not received, the process 1900 may continue to monitor the communication link (block 1910). However, if it is determined that the power-down signal is received, the process 1900 may transition two or more of a plurality of circuit elements of a SerDes circuit in a receiver network device from a power-up state to a power-down state (block 1920). In a non-limiting example, the two or more of the plurality of circuit elements may include two or more of a phase interpolator, a clock fan-up circuit, a CML driver circuit, or a termination circuit. In an example, the process 1900 may transition the CML driver circuit and the termination circuit from the power-up state to the power-down state in a staggered sequence.

In several more embodiments, the process 1900 may maintain an output voltage of the SerDes circuit at a configured level using a CM keeper circuit of the receiver network device upon the transition of the two or more of the plurality of circuit elements to the power-down state (block 1930). The process 1900 may enable the CM keeper circuit based on the transition of the two or more of the plurality of circuit elements to the power-down state. As may be understood, the maintaining of the output voltage of the SerDes circuit at the configured level is based on the enabling of the CM keeper circuit.

Although a specific embodiment for the process 1900 for transitioning two or more of a plurality of circuit elements of a SerDes circuit in a receiver network device from a power-up state to a power-down state in a staggered sequence suitable for carrying out the various steps, processes, methods, and operations described herein is discussed with respect to FIG. 19, any of a variety of systems and/or processes may be utilized in accordance with embodiments of the disclosure. For example, the process 1900 may transition one of the plurality of circuit elements of the SerDes circuit in the receiver network device from the power-up state to the power-down state in a staggered sequence. The elements depicted in FIG. 19 may also be interchangeable with other elements of FIGS. 1-18 and FIGS. 20-21 as required to realize a particularly desired embodiment.

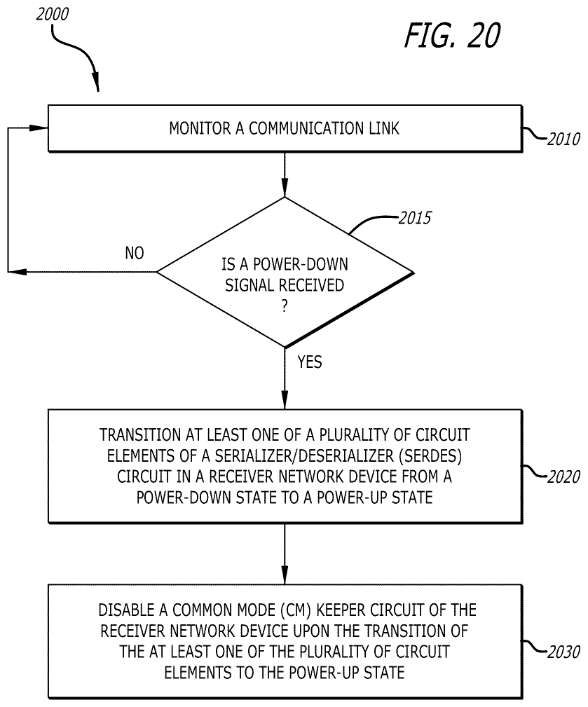

Referring to FIG. 20, a flowchart depicting a process 2000 for disabling a CM keeper circuit of a receiver network device upon transition of at least one of a plurality of circuit elements of a SerDes circuit to a power-up state in accordance with various embodiments of the disclosure is shown. In numerous embodiments, the process 2000 may monitor a communication link (block 2010). The process 2000 may monitor a communication link for incoming data. For example, the process 2000 may monitor the communication link for one or more signals from a transmitter network device. In an example, the one or more signals may include a power-up signal.

In many more embodiments, the process 2000 may determine whether a power-up signal is received (block 2015). The process 2000 may determine whether the power-up signal is received from a transmitter network device. In examples, the power-up signal may indicate a power-up state of at least one of a plurality of circuit elements of a SerDes circuit of the transmitter network device.

In further additional embodiments, if it is determined that the power-up signal is not received, the process 2000 may continue to monitor the communication link (block 2010). However, if it is determined that the power-up signal is received, the process 2000 may transition at least one of a plurality of circuit elements of a SerDes circuit in a receiver network device from a power-down state to a power-up state (block 2020). In a non-limiting example, the plurality of circuit elements may include two or more of a phase interpolator, a clock fan-up circuit, a CML driver circuit, and a termination circuit. In one or more embodiments, the process 2000 may transition one of the phase interpolator, the clock fan-up circuit, the CML driver circuit, or the termination circuit from the power-down state to the power-up state.

In further embodiments, the process 2000 may disable a CM keeper circuit of the receiver network device upon the transition of the at least one of the plurality of circuit elements to the power-up state (block 2030). The process 2000 may actuate a switching element between a CM keeper circuit of the receiver network device and one or more output terminals of the SerDes circuit of the receiver network device. In an example embodiment, the process 2000 may actuate the switching element to decouple the CM keeper circuit from the one or more output terminals of the SerDes circuit to disable the CM keeper circuit.

Although a specific embodiment for the process 2000 for disabling a CM keeper circuit of a receiver network device upon transition of at least one of a plurality of circuit elements of a SerDes circuit to a power-up state suitable for carrying out the various steps, processes, methods, and operations described herein is discussed with respect to FIG. 20, any of a variety of systems and/or processes may be utilized in accordance with embodiments of the disclosure. For example, the process 2000 may transition two or more of the plurality of circuit elements of the SerDes circuit in the receiver network device from the power-down state to the power-up state in a staggered sequence. The elements depicted in FIG. 20 may also be interchangeable with other elements of FIGS. 1-19 and FIG. 21 as required to realize a particularly desired embodiment.

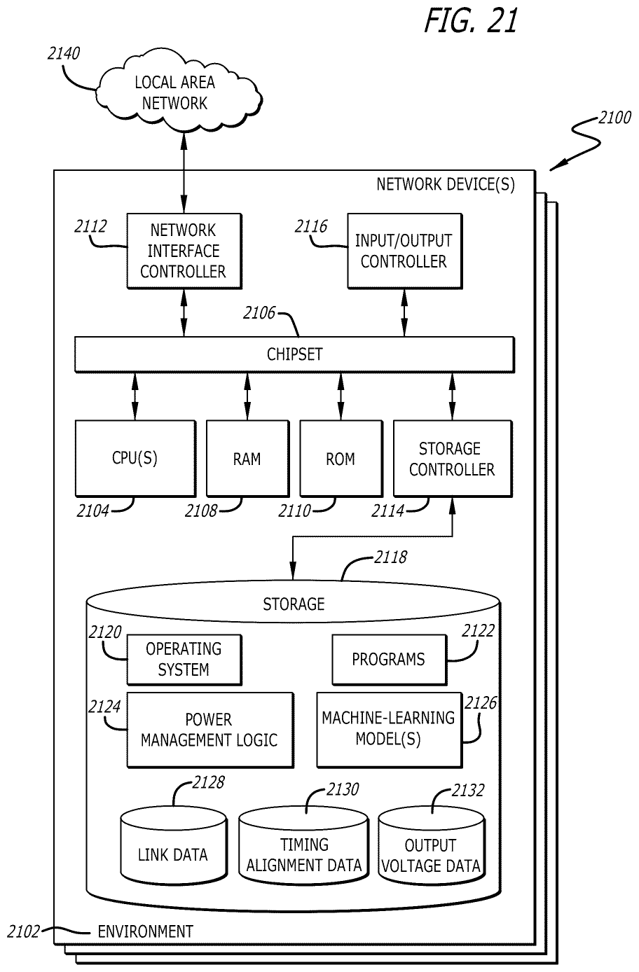

Referring to FIG. 21, a conceptual block diagram for one or more devices 2100 capable of executing components and logic for implementing the functionality and embodiments described above is shown. The embodiment of the conceptual block diagram depicted in FIG. 21 can illustrate a conventional server computer, workstation, desktop computer, laptop, tablet, network appliance, e-reader, smartphone, or other computing devices, and can be utilized to execute any of the application and/or logic components presented herein. The device 2100 may, in some examples, correspond to physical devices or virtual resources described herein.

In many embodiments, the device 2100 may include an environment 2102 such as a baseboard or a “motherboard,” in physical embodiments that can be configured as a printed circuit board with a multitude of components or devices connected by way of a system bus or other electrical communication paths. Conceptually, in virtualized embodiments, the environment 2102 may be a virtual environment that encompasses and executes the remaining components and resources of the device 2100. In more embodiments, one or more processors 2104, such as, but not limited to, CPUs, can be configured to operate in conjunction with a chipset 2106. The processor(s) 2104 can be standard programmable CPUs that perform arithmetic and logical operations necessary for the operation of the device 2100.

In additional embodiments, the processor(s) 2104 can perform one or more operations by transitioning from one discrete, physical state to the next through the manipulation of switching elements that differentiate between and change these states. Switching elements generally include electronic circuits that maintain one of two binary states, such as flip-flops, and electronic circuits that provide an output state based on the logical combination of the states of one or more other switching elements, such as logic gates. These basic switching elements can be combined to create more complex logic circuits, including registers, adders-subtractors, ALUs, floating-point units, or the like.

In various embodiments, the chipset 2106 may provide an interface between the processor(s) 2104 and the remainder of the components and devices within the environment 2102. The chipset 2106 can provide an interface to a RAM 2108, which can be used as the main memory in the device 2100 in some embodiments. The chipset 2106 can further be configured to provide an interface to a computer-readable storage medium such as a read-only memory (“ROM”) 2110 or a Non-volatile RAM (“NVRAM”) for storing basic routines that can help with various tasks such as, but not limited to, starting up the device 2100 and/or transferring information between the various components and devices. The ROM 2110 or the NVRAM can also store other application components necessary for the operation of the device 2100 in accordance with various embodiments described herein.

Different embodiments of the device 2100 can be configured to operate in a networked environment using logical connections to remote computing devices and computer systems through a network, such as the network 2140. The chipset 2106 can include functionality for providing network connectivity through a network interface controller (“NIC”) 2112, which may include a gigabit Ethernet adapter or similar component. The NIC 2112 can be capable of connecting the device 2100 to other devices over the network 2140. It is contemplated that multiple NICs 2112 may be present in the device 2100, connecting the device to other types of networks and remote systems.

In further embodiments, the device 2100 can be connected to a storage 2118 that provides non-volatile storage for data accessible by the device 2100. The storage 2118 can, for example, store an operating system 2120, programs 2122 (e.g., applications), and data 2128, 2130, and 2132, which are described in greater detail below. The storage 2118 can be connected to the environment 2102 through a storage controller 2114 connected to the chipset 2106. In various embodiments, the storage 2118 can include one or more physical storage units. The storage controller 2114 can interface with the physical storage units through a serial attached Small Computer System Interface (SCSI), that is, a serial attached SCSI (“SAS”) interface, a serial advanced technology attachment (“SATA”) interface, a fiber channel (“FC”) interface, or other type of interface for physically connecting and transferring data between computers and physical storage units.

The device 2100 can store data within the storage 2118 by transforming the physical state of the physical storage units to reflect the information being stored. The specific transformation of the physical state can depend on various factors. Examples of such factors can include, but are not limited to, the technology used to implement the physical storage units, whether the storage 2118 is characterized as primary storage, secondary storage, or the like.

For example, the device 2100 can store information within the storage 2118 by issuing instructions through the storage controller 2114 to alter the magnetic characteristics of a particular location within a magnetic disk drive unit, the reflective or refractive characteristics of a particular location in an optical storage unit, or the electrical characteristics of a particular capacitor, transistor, or other discrete component in a solid-state storage unit, or the like. Other transformations of physical media are possible without departing from the scope and spirit of the present description, with the foregoing examples provided only to facilitate this description. The device 2100 can further read or access information from the storage 2118 by detecting the physical states or characteristics of one or more particular locations within the physical storage units.

In addition to the storage 2118 described above, the device 2100 can have access to other computer-readable storage media to store and retrieve information, such as program modules, data structures, or other data. It should be appreciated by those skilled in the art that computer-readable storage media may refer to any available media that provides for the non-transitory storage of data and that can be accessed by the device 2100. In some examples, the operations performed by a cloud computing network, and/or any components included therein, may be supported by one or more devices similar to the device 2100. Stated otherwise, some or all of the operations performed by the cloud computing network, and/or any components included therein, may be performed by one or more devices 2100 operating in a cloud-based arrangement.

By way of example, and not limitation, computer-readable storage media can include volatile and non-volatile, removable and non-removable media implemented in any method or technology. Computer-readable storage media may include, but is not limited to, the RAM 2108, the ROM 2110, an Erasable Programmable ROM (“EPROM”), an Electrically Erasable Programmable ROM (“EEPROM”), a flash memory or other solid-state memory technology, a compact disc ROM (“CDROM”), a digital versatile disk (“DVD”), a high definition DVD (“HD-DVD”), BLU-RAY, or other optical storage, magnetic cassettes, magnetic tape, magnetic disk storage or other magnetic storage devices, or any other medium that can be used to store the desired information in a non-transitory fashion.

As mentioned briefly above, the storage 2118 can store the operating system 2120 utilized to control the operation of the device 2100. According to one embodiment, the operating system 2120 includes the LINUX operating system. According to another embodiment, the operating system 2120 includes the WINDOWS® SERVER operating system from MICROSOFT Corporation of Redmond, Washington. According to further embodiments, the operating system 2120 can include the UNIX operating system or one of its variants. It should be appreciated that other operating systems can also be utilized. The storage 2118 can store other system or application programs and data utilized by the device 2100.

In various embodiments, the storage 2118 or other computer-readable storage media is encoded with computer-executable instructions which, when loaded into the device 2100, may transform the device 2100 from a general-purpose computing system into a special-purpose computer capable of implementing the embodiments described herein. These computer-executable instructions may be stored as programs 2122 and transform the device 2100 by specifying how the processor(s) 2104 can transition between states, as described above. In some embodiments, the device 2100 has access to computer-readable storage media storing computer-executable instructions which, when executed by the device 2100, perform the various processes described above with regard to FIGS. 1-20.

In more embodiments, the device 2100 can also include computer-readable storage media having instructions stored thereupon for performing any of the other computer-implemented operations described herein. In still further embodiments, the device 2100 can also include one or more input/output controllers 2116 for receiving and processing input from a number of input devices, such as a keyboard, a mouse, a touchpad, a touch screen, an electronic stylus, or other type of input device. Similarly, an input/output controller 2116 can be configured to provide output to a display, such as a computer monitor, a flat panel display, a digital projector, a printer, or other type of output device. Those skilled in the art will recognize that the device 2100 might not include all of the components shown in FIG. 21, and can include other components that are not explicitly shown in FIG. 21, or might utilize an architecture completely different than that shown in FIG. 21.

As described above, the device 2100 may support a virtualization layer, such as one or more virtual resources executing on the device 2100. In some examples, the virtualization layer may be supported by a hypervisor that provides one or more virtual machines (“VMs”) running on the device 2100 to perform the functions described herein. The virtualization layer may generally support a virtual resource that performs at least a portion of the techniques described herein.

In many embodiments, the device 2100 can include a power management logic 2124 that can be configured to perform one or more of the various steps, processes, operations, and/or other methods that are described above. Often, the power management logic 2124 can be a set of instructions stored within a non-volatile memory that, when executed by the processor(s) 2104 can carry out these steps, etc. In some embodiments, the power management logic 2124 may be a client application that resides on a network-connected device, such as, but not limited to, a server, switch, personal or mobile computing device, or an access point.

In various embodiments, the power management logic 2124 may be configured to detect an absence of data for transmission. The power management logic 2124 may be configured to transition at least one of a plurality of circuit elements of a Serializer/Deserializer (SerDes) circuit from a power-up state to a power-down state based on the detection of the absence of data for transmission. In yet various embodiments, the power management logic 2124 may be configured to detect a presence of data for transmission. The power management logic 2124 may be configured to transition the at least one of the plurality of circuit elements of the SerDes circuit from the power-up state to the power-down state based on the detection of the presence of data for transmission.

In a number of embodiments, the storage 2118 can include link data 2128. The link data 2128 may be configured to indicate states of communication links. For example, the link data 2128 may indicate whether the communication links are in an active state or an idle state. In various embodiments, the storage 2118 can include timing alignment data 2130. The timing alignment data 2130 may include information about one or more reference clock signals generated by the SerDes circuit. In an example, a receiver device may maintain a timing alignment with the SerDes circuit during power-down state and power-up state based on the one or more reference clock signals. In a number of embodiments, the storage 2118 may include output voltage data 2132. The output voltage data 2132 may include data related to output voltages of the SerDes circuit. In an example, the output voltage may refer to electrical signals generated at output terminals of the SerDes circuit, which may represent serialized data being transmitted.

Finally, in many embodiments, data may be processed into a format usable by a machine-learning (“ML”) model 2126 (e.g., feature vectors), and or other processing techniques. The ML model 2126 may be any type of ML model, such as supervised models, reinforcement models, and/or unsupervised models. The ML model 2126 may include one or more of linear regression models, logistic regression models, decision trees, Naïve Bayes models, neural networks, k-means cluster models, random forest models, and/or other types of ML models 2126.

The ML model(s) 2126 can be configured to generate inferences to make predictions or draw conclusions from data. An inference can be considered the output of a process of applying a model to new data. This can occur by learning from data and using that learning to predict future outcomes. These predictions are based on patterns and relationships discovered within the data. To generate an inference, a trained model can take input data and produce a prediction or a decision. The input data can be in various forms, such as images, audio, text, or numerical data, depending on the type of problem the model was trained to solve. The output of the trained model can also vary depending on the problem, and can be a single number, a probability distribution, a set of labels, a decision about an action to take, etc. Ground truth for the ML model(s) 2126 may be generated by human/administrator verifications or may compare predicted outcomes with actual outcomes.

Although a specific embodiment for a device suitable for configuration with power management logic 2124 for carrying out the various steps, processes, methods, and operations described herein is discussed with respect to FIG. 21, any of a variety of systems and/or processes may be utilized in accordance with embodiments of the disclosure. For example, the device 2100 may be in a virtual environment such as a cloud-based network administration suite, or the device 2100 may be distributed across a variety of network devices or switches. The elements depicted in FIG. 21 may also be interchangeable with other elements of FIGS. 1-20 as required to realize a particularly desired embodiment.

Although the present disclosure has been described in certain specific aspects, many additional modifications and variations would be apparent to those skilled in the art. In particular, any of the various processes described above can be performed in alternative sequences and/or in parallel (on the same or different computing devices) to achieve similar results in a manner that is more appropriate to the requirements of a specific application. It is therefore to be understood that the present disclosure can be practiced other than specifically described without departing from the scope and spirit of the present disclosure. Thus, embodiments of the present disclosure should be considered in all respects as illustrative and not restrictive. It will be evident to the person skilled in the art to freely combine several or all of the embodiments discussed here as deemed suitable for a specific application of the disclosure. Throughout this disclosure, terms like “advantageous”, “exemplary” or “example” indicate elements or dimensions which are particularly suitable (but not essential) to the disclosure or an embodiment thereof and may be modified wherever deemed suitable by the skilled person, except where expressly required. Accordingly, the scope of the disclosure should be determined not by the embodiments illustrated, but by the appended claims and their equivalents.

Any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each and every problem sought to be resolved by the present disclosure, for solutions to such problems to be encompassed by the present claims. Furthermore, no element, component, or method step in the present disclosure is intended to be dedicated to the public regardless of whether the element, component, or method step is explicitly recited in the claims. Various changes and modifications in form, material, workpiece, and fabrication material detail can be made, without departing from the spirit and scope of the present disclosure, as set forth in the appended claims, as might be apparent to those of ordinary skill in the art, are also encompassed by the present disclosure.

What is claimed is:

1. A transmitter network device, comprising:
a Serializer/Deserializer (SerDes) circuit comprising a plurality of circuit elements;
one or more processors;
a memory communicatively coupled to the one or more processors, wherein the memory comprises a power management logic that is configured to:
detect an absence of data for transmission; and
transition at least one of the plurality of circuit elements from a power-up state to a power-down state based on the detection of the absence of data for transmission; and
a Common Mode (CM) keeper circuit is configured to maintain an output voltage of the SerDes circuit at a configured level upon the transition of the at least one of the plurality of circuit elements to the power-down state.

2. The transmitter network device of claim 1, wherein:
the at least one of plurality of circuit elements comprises two or more of the plurality of circuit elements, and
the power management logic is further configured to transition the two or more of the plurality of circuit elements from the power-up state to the power-down state in a staggered sequence based on the detection of the absence of data for transmission.

3. The transmitter network device of claim 1, wherein the plurality of circuit elements comprises two or more of:
a phase interpolator;
a clock fan-up circuit;
a Current Mode Logic (CML) driver circuit; and
a termination circuit.

4. The transmitter network device of claim 3, wherein:
the plurality of circuit elements further comprises the phase interpolator and one or more switches coupled to the phase interpolator, and
the power management logic is further configured to actuate the one or more switches to transition the phase interpolator from the power-up state to the power-down state.

5. The transmitter network device of claim 3, wherein:
the plurality of circuit elements further comprises the clock fan-up circuit and one or more switches coupled to the clock fan-up circuit, and
the power management logic is further configured to actuate the one or more switches to transition the clock fan-up circuit from the power-up state to the power-down state.

6. The transmitter network device of claim 3, wherein:
the plurality of circuit elements further comprises the termination circuit and one or more switches coupled to the termination circuit, and
the power management logic is further configured to actuate the one or more switches to transition the termination circuit from the power-up state to the power-down state.

7. The transmitter network device of claim 3, wherein:
the plurality of circuit elements further comprises the CML driver circuit and a current source coupled to the CML driver circuit, and
the power management logic is further configured to deactivate the current source to transition the CML driver circuit from the power-up state to the power-down state.

8. The transmitter network device of claim 7, wherein the power management logic is further configured to deactivate the current source after a configurable time period following a transition of the termination circuit from the power-up state to the power-down state.

9. The transmitter network device of claim 7, wherein:
the CML driver circuit comprises a pair of differential input terminals, and
the power management logic is further configured to control a gating of the pair of differential input terminals of the CML driver circuit, wherein the deactivation of the current source is based on the gating of the pair of differential input terminals.

10. The transmitter network device of claim 7, further comprising a switching element between the CM keeper circuit and one or more output terminals of the SerDes circuit, wherein the power management logic is further configured to:
actuate the switching element to couple the CM keeper circuit to the one or more output terminals of the SerDes circuit based on the transition of the CML driver circuit to the power-down state, and wherein the maintaining of the output voltage of the SerDes circuit at the configured level is based on the CM keeper circuit being coupled to the one or more output terminals.

11. The transmitter network device of claim 1, wherein the SerDes circuit is configured to:
generate a power-down signal; and
transmit the generated power-down signal to a receiver device indicating the power-down state of the at least one of the plurality of circuit elements.

12. The transmitter network device of claim 11, wherein the SerDes circuit is configured to transmit a reference clock signal to the receiver device upon the transition of the at least one of the plurality of circuit elements to the power-down state.

13. The transmitter network device of claim 1, wherein the power management logic is further configured to enable the CM keeper circuit based on the transition of the at least one of the plurality of circuit elements to the power-down state, and wherein the maintaining of the output voltage of the SerDes circuit at the configured level is based on the enabling of the CM keeper circuit.

14. The transmitter network device of claim 1, wherein the power management logic is further configured to:
detect a presence of data for transmission; and
transition the at least one of the plurality of circuit elements from the power-down state to the power-up state based on the detection of the presence of data for transmission.

15. The transmitter network device of claim 14, wherein the power management logic is further configured to disable the CM keeper circuit based on the transition of the at least one of the plurality of circuit elements from the power-down state to the power-up state.

16. A receiver network device, comprising:
a Serializer/Deserializer (SerDes) circuit comprising a plurality of circuit elements, wherein the SerDes circuit is configured to receive a power-down signal from a transmitter network device;
one or more processors;
a memory communicatively coupled to the one or more processors, wherein the memory comprises a power management logic that is configured to transition at least one of the plurality of circuit elements from a power-up state to a power-down state based on the reception of the power-down signal; and
a Common Mode (CM) keeper circuit, coupled to the SerDes circuit, is configured to maintain an output voltage of the SerDes circuit at a configured level upon the transition of the at least one of the plurality of circuit elements to the power-down state.

17. The receiver network device of claim 16, wherein:
the at least one of plurality of circuit elements comprises two or more of the plurality of circuit elements, and
the power management logic is further configured to transition the two or more of the plurality of circuit elements from the power-up state to the power-down state in a staggered sequence based on the reception of the power-down signal.

18. The receiver network device of claim 16, wherein the power management logic is further configured to:
receive a power-up signal from the transmitter network device; and
transition the at least one of the plurality of circuit elements from the power-down state to the power-up state based on the reception of the power-up signal.

19. The receiver network device of claim 16, wherein, the power management logic is further configured to:
receive a reference clock signal from the transmitter network device; and
maintain a timing alignment with the transmitter network device during the power-down state based on the received reference clock signal.

20. A method in a transmitter network device, comprising:
detecting an absence of data for transmission;
transitioning at least one of a plurality of circuit elements of a Serializer/Deserializer (SerDes) circuit in the transmitter network device from a power-up state to a power-down state based on the detection of the absence of data for transmission; and
maintaining an output voltage of the SerDes circuit at a configured level using a Common Mode (CM) keeper circuit of the transmitter network device upon the transition of the at least one of the plurality of circuit elements to the power-down state.
